(19) United States
(12) Patent Application Publication
(10) Pub. No.: US 2026/0175801 A1
(43) Pub. Date: Jun. 25, 2026

(54) METHODS AND SYSTEMS FOR LOW VOLTAGE DETECTION IN SEAT PERIPHERAL DEVICES FOR TRANSPORTATION VEHICLES

(71) Applicant: Panasonic Avionics Corporation, Irvine, CA (US)

(72) Inventors: Thong Pham, Irvine, CA (US); Vic Wu, Irvine, CA (US)

(21) Appl. No.: 18/614,149

(22) Filed: Mar. 22, 2024

(51) Int. Cl. B60R 16/03; B60N 2/90; B64D 11/00; B64D 11/06; B64D 45/00; G01R 19/165; H02J 1/08

(52) U.S. Cl. CPC B60R 16/03; B60N 2/90; B64D 11/0015; B64D 11/0624; B64D 45/00; G01R 19/16538; H02J 1/08; B64D 2221/00

(57) ABSTRACT

Methods and systems are provided for a transportation vehicle. A seat peripheral device includes a comparison component, a reference component, and a processor. The comparison component is configured to compare an input voltage and a reference voltage associated with a power supply component, where the input voltage is based on a supply voltage supplied to the seat peripheral device via a cable connected to the power supply component providing a DC voltage, and to output an output voltage based on whether the input voltage exceeds the reference voltage. The reference component is configured to generate the reference voltage based on the supply voltage when the DC voltage is at or above a threshold level. When the DC voltage drops below the threshold level during the power interruption, the reference component is configured to maintain the reference voltage at a same level as the reference voltage prior the power interruption.

### TECHNICAL FIELD

The present disclosure relates to transportation vehicles in general, and more particularly, to technology for detecting low voltage conditions where electric power falls below a desirable level in seat peripheral devices for transportation vehicles such as seat peripheral devices for passenger seats within an aircraft.

### BACKGROUND

Transportation vehicles, for example, aircraft, trains, buses, recreation vehicle, boats and other similar vehicles use various computing devices for providing various functions, including entertainment, system control, content storage, and other functions. These computing devices include hardware (for example, servers, switches, network interface cards, storage adapters, storage devices and others) and software (for example, server applications, operating systems, firmware, management applications, application programming interface (APIs) and others).

Aircrafts today have individualized functional equipment dedicated to a passenger seat, which can be utilized by a passenger, such as adjustable seats, adjustable environmental controls, adjustable lighting, telephony systems, video and/or audio entertainment systems, crew communication systems, and the like. For example, many commercial airplanes have individualized video and audio entertainment systems, often referred to as “in-flight entertainment” or “IFE” systems.

Seat peripheral devices associated with seat devices for transportation vehicles are often powered by an alternating current (AC) power supply. The AC power supply may experience short interruptions (e.g., up to 200 milliseconds) during which the AC power is cut off or is not sufficiently supplied. During the short AC interruptions, the seat peripheral devices are generally supplied by a back-up power to avoid rebooting or reinitializing of the seat peripheral devices. When the AC power supply detects an interruption, an interruption voltage is supplied for a set maximum duration (e.g., 200 milliseconds). If the interruption ends and the power is restored before the maximum duration, then the seat peripheral devices may return to their previous operation states, without rebooting or reinitializing. If the voltage level during the interruption is not maintained at the interruption voltage and drops further below the interruption voltage, then a warning signal may be provided for a low voltage condition. However, various factors may contribute to errors in detecting the low voltage condition. Continuous efforts are being made to develop technologies that can detect the low voltage condition with improved accuracy.

### BRIEF DESCRIPTION OF THE DRAWINGS

The various features of the present disclosure will now be described with reference to the drawings of the various aspects disclosed herein. In the drawings, the same components may have the same reference numerals. The illustrated aspects are intended to illustrate, but not to limit the present disclosure. The drawings include the following Figures:

FIG. 1A shows an example of an operating environment for implementing the various aspects of the present disclosure on an aircraft;

FIG. 1B shows an example of the operating environment on a non-aircraft transportation vehicle type, according to one aspect of the present disclosure;

FIG. 2 shows an example of a content distribution system, used according to one aspect of the present disclosure;

FIG. 3A shows an example of a system configured to operate within a transportation vehicle, according to one aspect of the present disclosure;

FIG. 3B shows an example of a system for detecting a low voltage condition utilizing a fixed reference voltage, according to some aspects;

FIG. 3C shows an example of a system for detecting a low voltage condition within a transportation vehicle by utilizing a reference voltage generated based on a supply voltage, according to one aspect of the present disclosure.

FIG. 3D shows an example system with a circuit diagram of various components for detecting a low voltage condition within a transportation vehicle by utilizing a reference voltage generated based on a supply voltage, according to an aspect of the present disclosure;

FIG. 3E shows another example system with a circuit diagram of various components for detecting a low voltage condition within a transportation vehicle by utilizing a reference voltage generated based on a supply voltage, according to an aspect of the present disclosure;

FIG. 4A shows a process for detecting a low voltage condition at a seat peripheral device for a transportation vehicle using a seat peripheral component coupled to a passenger seat, according to one aspect of the present disclosure;

FIG. 4B shows a process for detecting a low voltage condition at a seat peripheral device for a transportation vehicle using a seat peripheral component coupled to a passenger seat, continuing from the process of FIG. 4A, according to one aspect of the present disclosure; and

FIG. 5 shows a block diagram of a computing system, used according to one aspect of the present disclosure.

### DETAILED DESCRIPTION

In one aspect, innovative technology is disclosed for detecting a low voltage condition that may be caused by a power interruption at a power supply component providing power to a seat peripheral device for a transportation vehicle via a cable. The voltage provided by the power supply component at one end of the cable may be different from a supply voltage provided to the seat peripheral device at the other end of the cable, due to various factors such as a length of the cable and a power dissipation requirement of the seat peripheral device. Although the seat peripheral device may compare the supply voltage with a fixed reference voltage that remains unchanged, this approach may not be desired because the supply voltage may vary between seat peripheral devices depending on cable lengths to the seat peripheral devices and/or power dissipation requirements of the seat peripheral device. Hence, as described below in detail, the innovative technology generates a reference voltage based on the supply voltage when there is no power interruption and maintains the reference voltage at a same level as the reference voltage prior to a power interruption when the power interruption occurs. This reference voltage is compared with an input voltage that is based on the supply voltage, to indicate whether there is a low voltage condition. Details regarding the innovative techniques are provided below.

As a preliminary note, the terms “component”, “module”, “system”, and the like as used herein are intended to refer to a computer-related entity, either software-executing general-purpose processor, hardware, firmware or a combination thereof. For example, a component may be, but is not limited to being, a process running on a hardware processor, a hardware processor, an object, an executable, a thread of execution, a program, and/or a computer.

By way of illustration, both an application running on a server and the server can be a component. One or more components may reside within a process and/or thread of execution, and a component may be localized on one computer and/or distributed between two or more computers. Also, these components can execute from various computer readable media having various data structures stored thereon. The components may communicate via local and/or remote processes such as in accordance with a signal having one or more data packets (e.g., data from one component interacting with another component in a local system, distributed system, and/or across a network such as the Internet with other systems via the signal).

Computer executable components can be stored, for example, on non-transitory, computer/machine readable media including, but not limited to, an ASIC (application specific integrated circuit), CD (compact disc), DVD (digital video disk), ROM (read only memory), hard disk, EEPROM (electrically erasable programmable read only memory), solid state memory device or any other storage device, in accordance with the claimed subject matter.

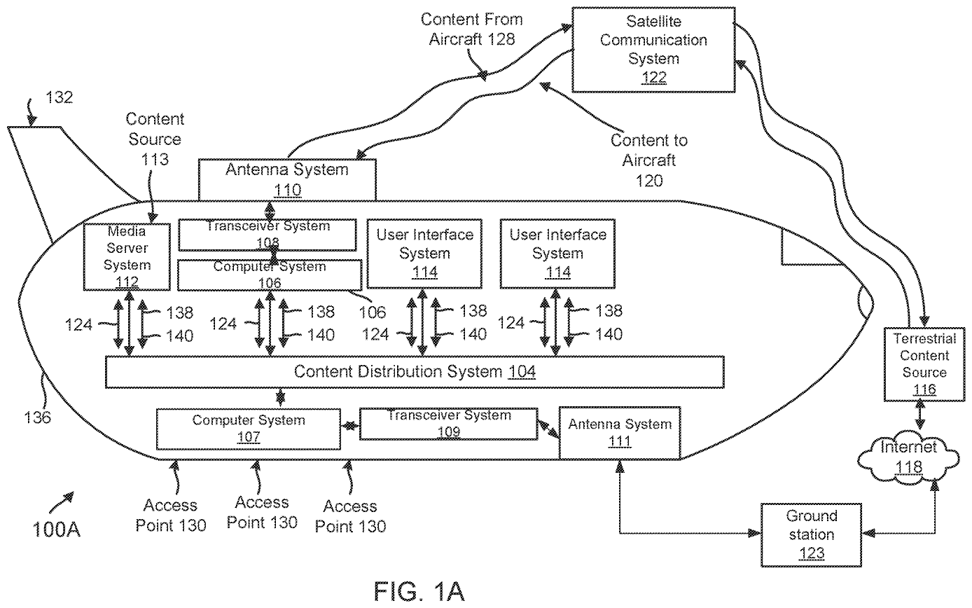

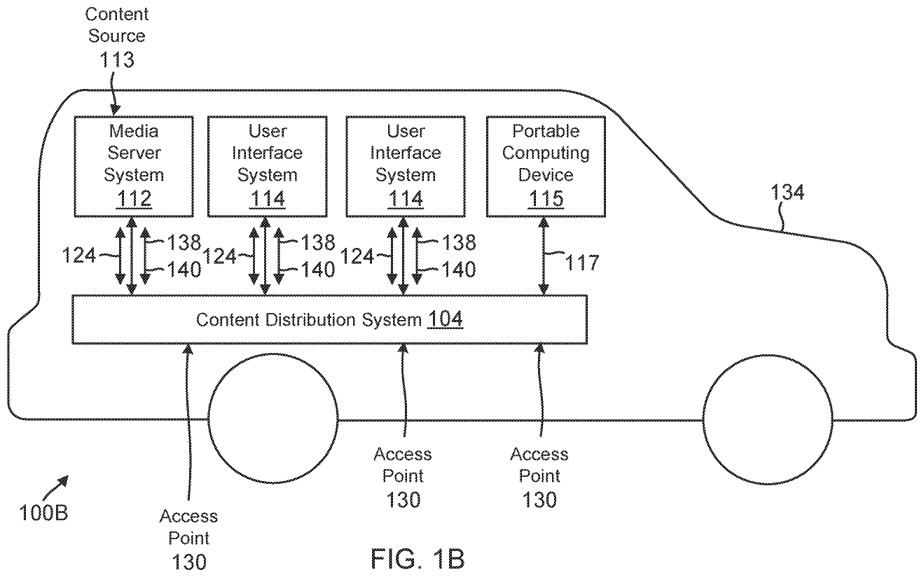

Vehicle Information System: FIG. 1A shows an example of a generic vehicle information system 100A (also referred to as system 100A) that can be configured for installation aboard an aircraft 132, according to one aspect of the present disclosure. When installed on an aircraft, system 100A can comprise an aircraft passenger IFE system, such as the Series 2000, 3000, eFX, eX 2, eXW,, eX 3, NEXT, and/or any other in-flight entertainment system developed and provided by Panasonic Avionics Corporation (without derogation of any trademark rights of Panasonic Avionics Corporation) of Lake Forest, California, the assignee of this application.

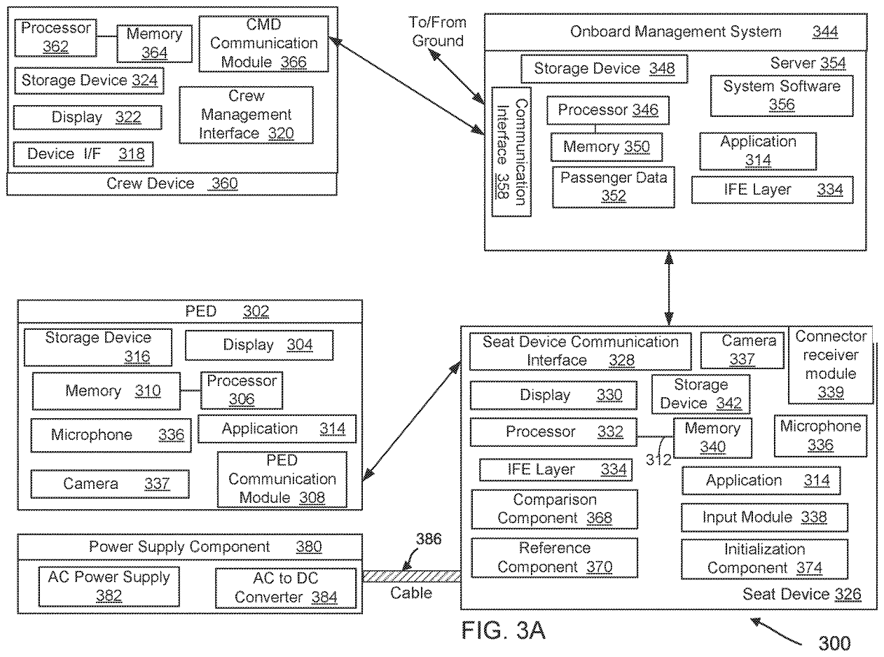

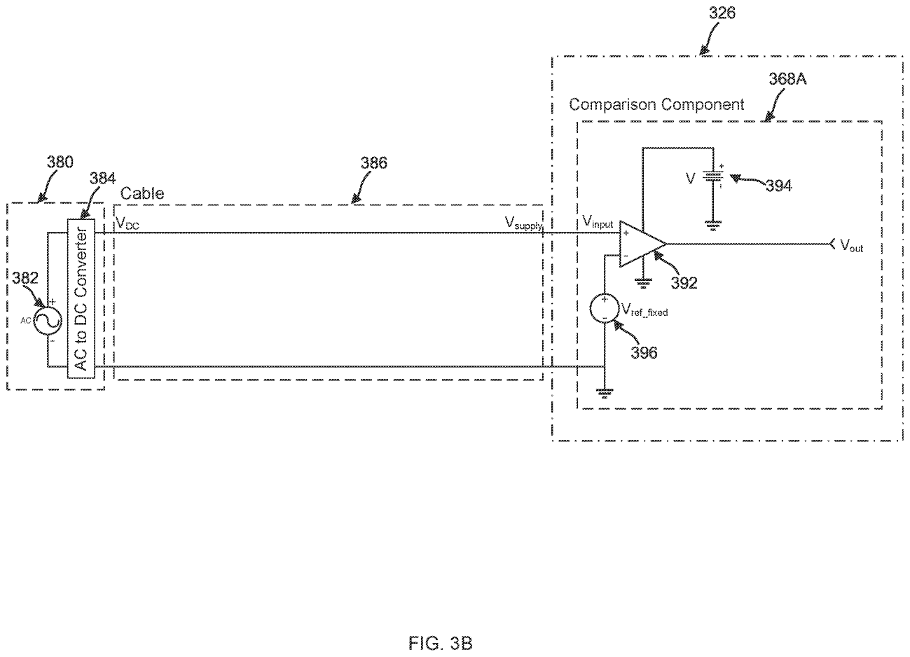

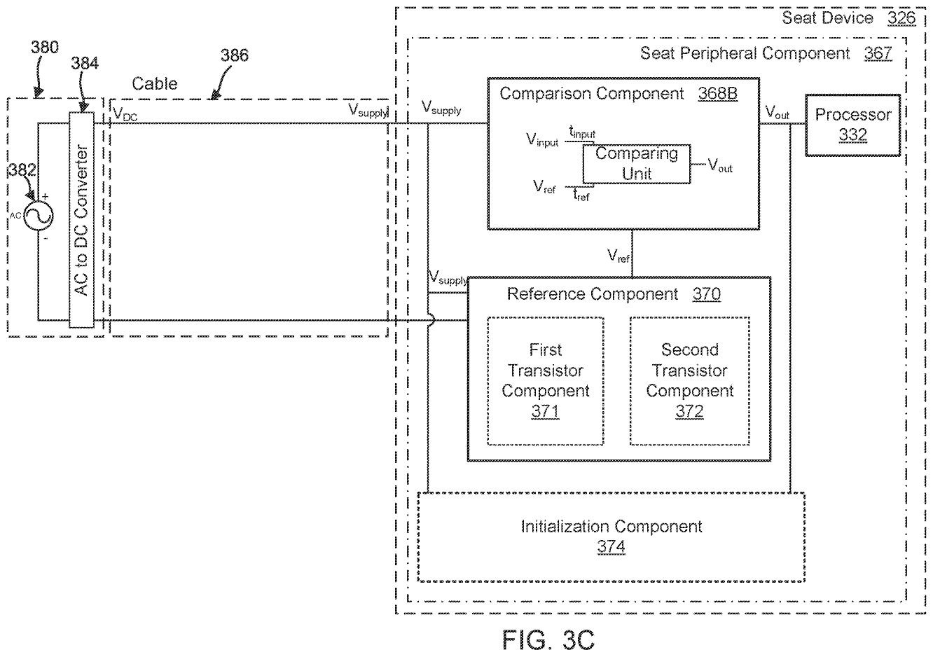

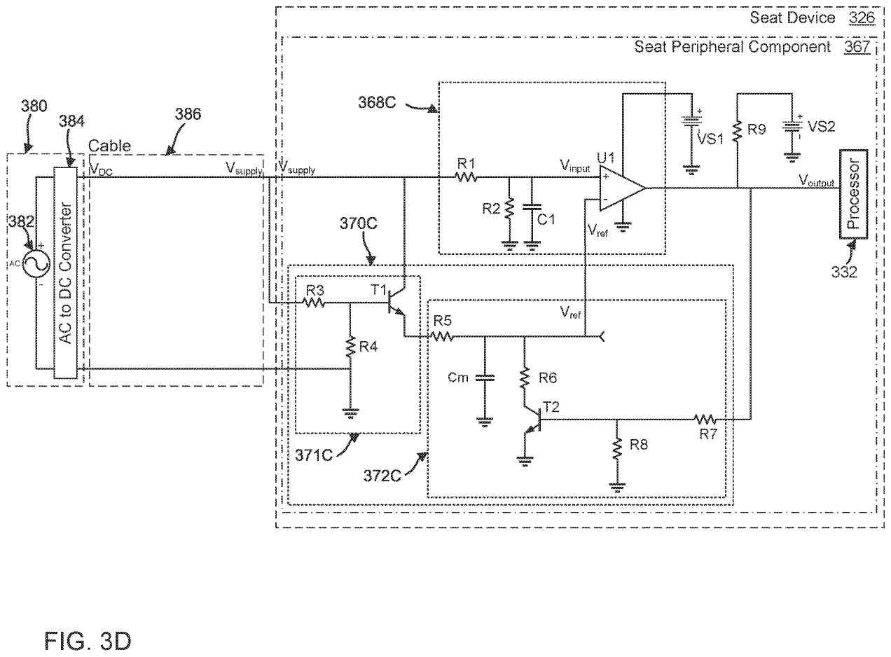

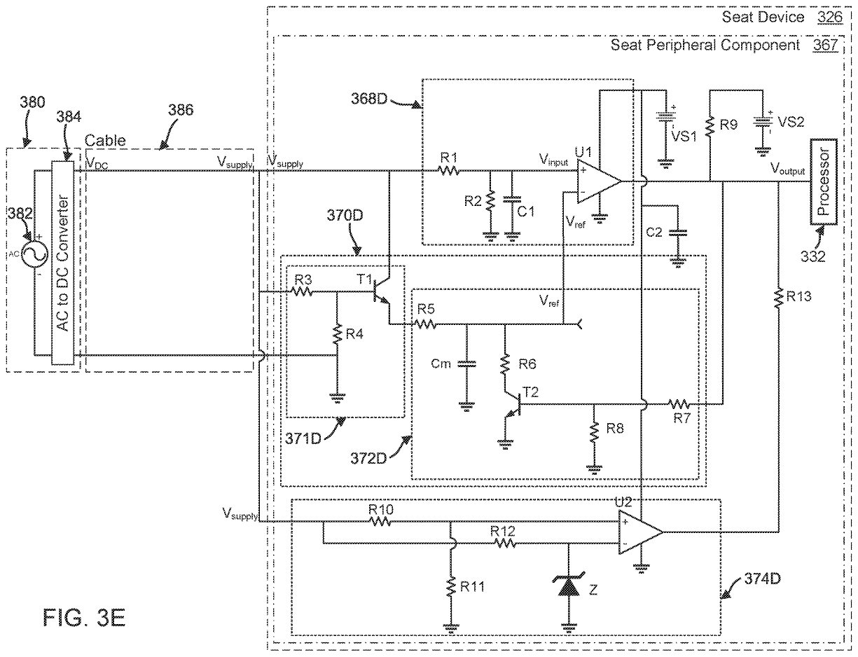

System 100A may include one or more content source 113 and one or more user (or passenger) interface systems (may also be referred to as a seat device/seatback device/IFE device 326 described below with respect to FIG. 3) 114 that communicate with a real-time content distribution system 104.

As an example, the content sources 113 may include one or more internal content sources, such as a media server system 112, that are installed aboard the aircraft 132, one or more remote (or terrestrial) content sources 116 that can be external from the aircraft 132, or a distributed content system. The media server system 112 can be provided as an information system controller for providing overall system control functions for system 100A and/or for storing viewing content 124, including pre-programmed viewing content and/or content 120 downloaded to the aircraft, as desired. The viewing content 124 can include television programming content, music content, podcast content, photograph album content, audiobook content, and/or movie content without limitation. The viewing content as shown and described herein is not exhaustive and are provided herein for purposes of illustration only and not for purposes of limitation.

The server system 112 can include, and/or communicate with, one or more conventional peripheral media storage systems (not shown), including optical media devices, such as a digital video disk (DVD) system or a compact disk (CD) system, and/or magnetic media systems, such as a solid state drive (SSD) system, or a hard disk drive (HDD) system, of any suitable kind, for storing preprogrammed content and/or downloaded content 120.

The viewing content 124 can comprise any conventional type of audio and/or video viewing content, such as stored (or time-delayed) viewing content and/or live (or real-time) viewing content. As desired, the viewing content 124 can include geographical information. Alternatively, and/or additionally, to entertainment content, such as live satellite television programming and/or live satellite radio programming and/or live wireless video/audio streaming, the viewing content likewise can include two-way communications, such as real-time access to the Internet 118 and/or telecommunications and/or a ground station 123 that communicates through an antenna 111 to a transceiver system 109, and a computer system 107 (similar to computer system 106). The functionality of computer system 107 is like computing system 106 for distributing content using the content distribution system 104 described herein. It is noteworthy that although two antenna systems 110/111 have been shown in FIG. 1A, the adaptive aspects disclosed herein may be implemented by fewer or more antenna systems.

Being configured to distribute and/or present the viewing content 124 provided by one or more selected content sources 113, system 100A can communicate with the content sources 113 in real time and in any conventional manner, including via wired and/or wireless communications. System 100A and the terrestrial content source 116, for example, can communicate directly and/or indirectly via an intermediate communication system, such as a satellite communication system 122 or the ground station 123.

System 100A can receive content 120 from a selected terrestrial content source 116 and/or transmit (upload) content 128, including navigation and other control instructions, to the terrestrial content source 116. In one aspect, content 120 includes media content that is stored persistently on the aircraft for passenger consumption. The media content for persistence storage is handled differently than live television content, as described below. As desired, terrestrial content source 116 can be configured to communicate with other terrestrial content sources (not shown). Terrestrial content source 116 is shown as providing access to the Internet 118. Although shown and described as comprising the satellite communication system 122 and the cellular base station 123 for purposes of illustration, the communication system can comprise any conventional type of wireless communication system, such as any wireless communication system and/or an Aircraft Ground Information System (AGIS) communication system.

To facilitate communications with the terrestrial content sources 116, system 100A may also include an antenna system 110 and a transceiver system 108 for receiving the viewing content from the remote (or terrestrial) content sources 116. The antenna system 110 preferably is disposed outside, such as an exterior surface of a fuselage 136 of the aircraft 132. The antenna system 110 can receive viewing content 124 from the terrestrial content source 116 and provide the received viewing content 124, as processed by the transceiver system (may also referred to as broadband controller) 108, to a computer system 106 of system 100A. The computer system 106 can provide the received viewing content 124 to the media (or content) server system 112 and/or directly to one or more of the user interfaces 114 including a PED, as desired. Although shown and described as being separate systems for purposes of illustration, the computer system 106 and the media server system 112 can be at least partially integrated.

The user interface system 114 may be computing terminals in communication with an access point 130. The user interface system 114 provides a display device to view content. The user interface system 114 includes a hardware interface to connect to an access point 130 that provides a wired and/or a wireless connection for the user interface system. In at least one embodiment, the user interface system 114 comprises a software application that a user downloads and installs on a PED to receive and view content via a wireless access point 130. While bandwidth limitation issues may occur in a wired system on a vehicle, such as an aircraft 132, in general the wired portion of the vehicle information 100A system is designed with enough bandwidth to support all users aboard the vehicle, i.e., passengers.

The user interface system 114 can include an input system (not shown) for permitting the user (or passenger) to communicate with system 100A, such as via an exchange of control signals 138. For example, the input system can permit the user to input one or more user instructions 140 for controlling the operation of system 100A. Illustrative user instructions 140 can include instructions for initiating communication with the content source 113, instructions for selecting viewing content 124 for presentation, and/or instructions for controlling the presentation of the selected viewing content 124. If a fee is required for accessing the viewing content 124 or for any other reason, payment information likewise can be entered via the input system. The input system can be provided in any conventional manner and typically includes a touch screen, application programming interface (API), one or more switches (or pushbuttons), such as a keyboard or a keypad, and/or a pointing device, such as a mouse, trackball, or stylus.

In one aspect, the user interface system 114 is provided on individual passenger seats of aircraft 132. The user interface system 114 can be adapted to different aircraft and seating arrangements and the adaptive aspects described herein are not limited to any specific seat arrangements or user interface types.

FIG. 1B shows an example of implementing the vehicle information system 100B (may be referred to as system 100B) on an automobile 134 that may include a bus, a recreational vehicle, a boat, and/or a train, or any other type of passenger vehicle without limitation. The various components of system 100B may be like the components of system 100A described above with respect to FIG. 1A and for brevity are not described again.

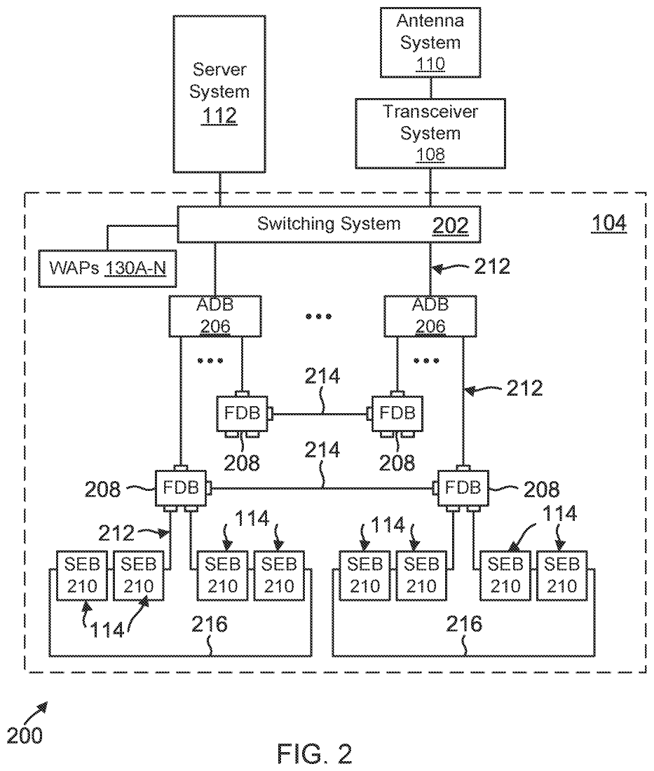

Content Distribution System: FIG. 2 illustrates an example of the content distribution system 104 for the vehicle information system 200 (similar to 100A/100B), according to one aspect of the present disclosure. The content distribution system 104 couples, and supports communication between the server system 112, and the plurality of user interface systems 114. The content distribution system 104, for example, can be provided as a conventional wired and/or wireless communication network, including a telephone network, a local area network (LAN), a wide area network (WAN), a campus area network (CAN), personal area network (PAN) and/or a wireless local area network (WLAN) of any kind. Exemplary wireless local area networks include wireless fidelity (Wi-Fi) networks in accordance with Institute of Electrical and Electronics Engineers (IEEE) Standard 802.11 and/or wireless metropolitan-area networks (MANs), which also are known as WiMax Wireless Broadband, in accordance with IEEE Standard 802.16.

Preferably being configured to support high data transfer rates, the content distribution system 104 may comprise a high-speed Ethernet network, such as any type of Fast Ethernet (such as 100 Base-X and/or 100 Base-T) communication network and/or Gigabit (such as 1000 Base-X and/or 1000 Base-T) Ethernet communication network, with a typical data transfer rate of at least approximately one hundred megabits per second (100 Mbps) or any other transfer rate. To achieve high data transfer rates in a wireless communications environment, free-space optics (or laser) technology, millimeter wave (or microwave) technology, and/or Ultra-Wideband (UWB) technology can be utilized to support communications among the various system resources, as desired.

As illustrated in FIG. 2, the distribution system 104 can be provided as a plurality of area distribution boxes (ADBs) 206, a plurality of floor disconnect boxes (FDBs) 208, and a plurality of seat electronics boxes (SEBs) (and/or video seat electronics boxes (VSEBs) and/or premium seat electronics boxes (PSEBs)) 210 being configured to communicate in real time via a plurality of wired and/or wireless communication connections 212.

The distribution system 104 likewise can include a switching system 202 for providing an interface between the distribution system 104 and the server system 112. The switching system 202 can comprise a conventional switching system, such as an Ethernet switching system, and is configured to couple the server system 112 with the ADBs 206. Each of the ADBs 206 is coupled with, and communicates with, the switching system 202. In addition, the distribution system 104 includes one or more wireless access points (WAPs) (130A to 130N) connected in communication with the switch system 202 for wireless distribution of content to user interface systems 114 including personal electronic devices (PEDs).

Each of the ADBs 202, in turn, is coupled with, and communicates with, at least one FDB 208. Although the ADBs 206 and the associated FDBs 208 can be coupled in any conventional configuration, the associated FDBs 208 preferably are disposed in a star network topology about a central ADB 206 as illustrated in FIG. 2. Each FDB 208 is coupled with, and services, a plurality of daisy-chains of SEBs 210. The SEBs 210, in turn, are configured to communicate with the user interface systems 114. Each SEB 210 can support one or more of the user interface systems 114.

The switching systems 202, the ADBs 206, the FDBs 208, the SEBs (and/or VSEBs), and/or PSEBs) 210, the antenna system 110 (or 111), the transceiver system 108, the content source 113, the server system 112, and other system resources of the vehicle information system preferably are provided as line replaceable units (LRUs). The use of LRUs facilitate maintenance of the vehicle information system 200 because a defective LRU can simply be removed from the vehicle information system 200 and replaced with a new (or different) LRU. The defective LRU thereafter can be repaired for subsequent installation. Advantageously, the use of LRUs can promote flexibility in configuring the content distribution system 104 by permitting ready modification of the number, arrangement, and/or configuration of the system resources of the content distribution system 104. The content distribution system 104 likewise can be readily upgraded by replacing any obsolete LRUs with new LRUs.

Distribution system 104 can include at least one FDB internal port bypass connection 214 and/or at least one SEB loopback connection 216. Each FDB internal port bypass connection 214 is a communication connection 212 that permits FDBs 208 associated with different ADBs 206 to directly communicate. Each SEB loopback connection 216 is a communication connection 212 that directly couples the last SEB 210 in each daisy-chain of seat electronics boxes 210 for a selected FDB 208 as shown in FIG. 2. Each SEB loopback connection 216 therefore forms a loopback path among the daisy-chained seat electronics boxes 210 coupled with the relevant FDB 208.

It is noteworthy that the various aspects of the present disclosure may be implemented without using FDB 208. When FDB 208 is not used, ADB 206 communicates directly with SEB 210 and/or server system 112 may communicate directly with SEB 210 or the seats. The various aspects of the present disclosure are not limited to any specific network configuration.

System 300: FIG. 3A shows an example of a system 300 configured to operate within a transportation vehicle system (e.g., an onboard management system 344 executing an IFE layer, may also be referred to as the IFE system), according to one aspect of the present disclosure. In one aspect, system 300 includes the onboard management system 344 with a server 354, a seat device 326, a PED 302, when authorized, and a crew device (may be referred to as “CMD”) 360, when authorized. In yet another aspect, system 300 includes the CMD 360 and the PED 302 or the CMD 360 and the seat device 326, respectively. System 300 further includes a power supply component 380 that supplies direct current (DC) power at least to the seat device 326. The power supply component 380 includes an alternating current (AC) power supply 382 that supplies AC power, and an AC to DC converter 384 configured to convert the AC voltage from the AC power supply 382 to the DC voltage, which provided a cable 386 to be supplied to the seat device 326 as a supply voltage.

In one aspect, the onboard management system 344 includes server 354 (similar to the media server 112 and/or computer system 106/107 described above with respect to FIG. 1A/1B). The server 354 includes a processor 346 that has access to a memory 350 via a bus system/interconnect (similar to 312 on seat device 326). The bus system may represent any one or more separate physical buses and/or point-to-point connections, connected by appropriate bridges, adapters and/or controllers. The bus system may include, for example, a system bus, a Peripheral Component Interconnect (PCI) bus, a PCI-Express bus, a HyperTransport or industry standard architecture (ISA) bus, a small computer system interface (SCSI) bus, a universal serial bus (USB), or an Institute of Electrical and Electronics Engineers (IEEE) standard 1394 bus (sometimes referred to as “Firewire”) or any other interconnect type.

Processor 346 may be, or may include, one or more programmable, hardware-based, general-purpose or special-purpose microprocessors, digital signal processors (DSPs), programmable controllers, application specific integrated circuits (ASICs), programmable logic devices (PLDs), or the like, or a combination of such devices.

Processor 346 has access to a storage device 348 that may be used to store data (for example, passenger data 352, and applications and program files, including system software 356, application 314, and others.

In one aspect, system software 356 is executed by processor 346 to control the overall operation of the server 354. Application 314 may be downloaded from server 354 by passengers using an authorized PED 302 paired with the seat device 326 and/or server 354 for accessing digital content.

In one aspect, the onboard management system 344 maintains flight and passenger data 352 (may also be referred to as data 352), for example, flight itinerary including origin location, layover locations, destination location, arrival time and other information. Data 352 may also include passenger data that identifies each passenger for a flight, a seat assigned to a passenger, a language preference for the passenger, and any other information that can uniquely identify the passengers. Data 352 may be retrieved from a ground system before flight departure.

In one aspect, server 354 communicates with CMD 360, PED 302 and/or seat device 326 via the communication interface 358. The communication interface 358 may also be used to receive information from the ground, for example, data 352 and other information. The communication interface 358 includes one or more interfaces for a wired and/or wireless connection, as described above with respect to FIG. 1A/1B and 2.

In one aspect seat device 326 includes a display device 330, a processor 332, a memory 340, a seat device communication interface (also referred to as communication interface) 328 and a local storage device 342 for storing content. The seat device may optionally include a camera 337 and a microphone 336. The camera may be used to take pictures and videos and the microphone may be used for receiving voice input.

In one aspect, the seat device 326 receives user input/requests via an input module 338. The input module 338 may be configured to use a local touch screen included with display 330, a local virtual keyboard, an external mouse, external keyboard or any other input device.

In one aspect, processor 332 has access to memory 340 via an interconnect 312. Processor 332 may be, or may include, one or more programmable general-purpose or special-purpose microprocessors, digital signal processors (DSPs), programmable controllers, application specific integrated circuits (ASICs), programmable logic devices (PLDs), or the like, or a combination of such devices.

The bus system 312 is an abstraction that represents any one or more separate physical buses and/or point-to-point connections, connected by appropriate bridges, adapters and/or controllers. The bus system 312, therefore, may include, for example, a system bus, a Peripheral Component Interconnect (PCI) bus, a PCI-Express bus, a HyperTransport or industry standard architecture (ISA) bus, a small computer system interface (SCSI) bus, a universal serial bus (USB), or an Institute of Electrical and Electronics Engineers (IEEE) standard 1394 bus (sometimes referred to as “Firewire”) or any other interconnect type.

In one aspect, processor 332 executes an IFE layer 334 out of memory 340. The IFE layer 334 provides in-flight entertainment and other options for users. The IFE layer 334 provides audio/video content as well as controls for accessing the content.

In one aspect, the IFE layer 334 uses the seat device communication interface 328 to interface with the PED 302 and/or onboard management system 344. The communication interface 328 includes logic and circuitry for interfacing with the onboard management system 344 and/or PED 302. In one aspect, the communication interface 328 may use a wireless and/or wired connection for such communication.

In another aspect, the seat device 326 may also execute the application 314 that may be used by the passenger to view media content or various computing functions that are enabled by the seat device 326. Application 314 when executed by the seat device 326 may have different functionality compared to when application 314 is executed by the PED 302.

In one aspect, the seat device 326 may be supplied with the supply voltage via the cable 386 connected to the power supply component 380. As discussed above, the AC to DC converter 384 of the power supply component 380 provides the DC voltage to at a first end of the cable 386 at the power supply component 380, such that the supply voltage is provided at the seat device 326 at a second end of the cable 386.

In one aspect, the seat device 326 may further include a comparison component 368 configured to compare two voltage values and output an output voltage/signal based on the comparison. In an aspect, the comparison component 368 may be configured to compare an input voltage and a reference voltage, where the comparison component 368 outputs a first output voltage if the input voltage exceeds the reference voltage and outputs a second output voltage if the input voltage is less than or equal to the reference voltage. The output voltage from the comparison component 368 may be provided to the processor 332, such that the processor 332 may perform an operation based on the output voltage. The seat device 326 may further include a reference component 370 configured to generate the reference voltage and provide the reference voltage to the comparison component 368. Additional details about the comparison component 368 and the reference component 370 are provided infra.

In one aspect, the seat device 326 may further include an initialization component 374 configured to maintain an output voltage of the comparison component 368 as the second output voltage during initialization of the seat device 326. The initialization component 374 may be an optional component that may be omitted. Additional details about the initialization component 374 are provided infra.

The seat device 326 on the aircraft may be part of the user interface system 114 or interfaces with the user interface system 114 also described above with respect to FIG. 1A/1B. It is noteworthy that seat device 326 need not be mounted on the back of a seat and may be supported from other structures, such as a bulkhead, wall, arm of a seat, etc. The adaptive aspects of the present disclosure are not limited to any specific location or orientation of the seat device 326.

In one aspect, server 354 communicates with the CMD 360 that may be a mobile phone, a notebook, a tablet, a laptop or any other similar device. CMD 360 may include a processor 362 that has access to a memory 364 via a bus system/interconnect (similar to 312) for executing stored instructions. The bus system may represent any one or more separate physical buses and/or point-to-point connections, connected by appropriate bridges, adapters and/or controllers. The bus system may include, for example, a system bus, a Peripheral Component Interconnect (PCI) bus, a PCI-Express bus, a HyperTransport or industry standard architecture (ISA) bus, a small computer system interface (SCSI) bus, a universal serial bus (USB), or an Institute of Electrical and Electronics Engineers (IEEE) standard 1394 bus (sometimes referred to as “Firewire”) or any other interconnect type.

Processor 362 may be, or may include, one or more programmable, hardware based, general-purpose or special-purpose microprocessors, digital signal processors (DSPs), programmable controllers, application specific integrated circuits (ASICs), programmable logic devices (PLDs), or the like, or a combination of such hardware devices.

In one aspect, CMD 360 includes a display 322 to display information. Display 322 may also include a touch screen for receiving input commands. CMD 360 typically includes a microphone (not shown) for receiving voice input. CMD 360 may also include a camera (not shown) for taking pictures or making a video. The CMD 360 may also include a storage device 324 that may include any storage medium for storing data in a non-volatile manner, such as one or more magnetic or optical based disks, flash memory, or solid-state drive. The storage device 316 may be used to store a device interface 318, may also be referred to as a “crew management interface (CMI)” 318 that may be executed out of memory 364.

The CMI 318 enables the CMD 360 to interface with the onboard management system 344 via a CMD communication module 366. The CMD 360 may present one or more APIs to the onboard management system 344 to retrieve passenger/flight data and update data structure 352. The non-limiting API format and syntax will depend on the protocols used by the CMD 360 and the onboard management system 344.

In one aspect, the CMD communication module 366 is also used to communicate with the seat device 326, when installed, and one or more PEDs 302. CMI 320 receives information regarding one or more seat attributes that do not meet take-off and/or landing conditions. CMI 320 notifies the seat device and/or paired PED 302 if a passenger needs to take action (e.g., move the passenger seat, tray table, window or any other action.

In one aspect, the CMD communication module 366 may include one or more interfaces to communicate with different devices, including Wi-Fi interface, Bluetooth interface, NFC (Near Field Communication) interface and others. The adaptive aspects described herein are not limited to any specific interface. It is noteworthy that although a single block is shown for the CMD communication module 366 for convenience, the communication module may have different interface, cards, logic and circuitry to comply with the different communication protocols/standards.

In one aspect, the PED 302 is securely paired with the seat device 326. The term “pair” means that PED 302 is associated and authenticated by the seat device 326 and/or server 354 to send and receive information.

As an example, the PED 302 may be a mobile phone, a notebook, a tablet, a laptop or any other computing device. PED 302 may include a processor 306 that has access to a memory 310 via a bus system/interconnect (similar to 312 on the seat device 326) for executing stored instructions. The bus system may represent any one or more separate physical buses and/or point-to-point connections, connected by appropriate bridges, adapters and/or controllers. The bus system may include, for example, a system bus, a Peripheral Component Interconnect (PCI) bus, a PCI-Express bus, a HyperTransport or industry standard architecture (ISA) bus, a small computer system interface (SCSI) bus, a universal serial bus (USB), or an Institute of Electrical and Electronics Engineers (IEEE) standard 1394 bus (sometimes referred to as “Firewire”) or any other interconnect type.

Processor 306 may be, or may include, one or more programmable, hardware based, general-purpose or special-purpose microprocessors, digital signal processors (DSPs), programmable controllers, application specific integrated circuits (ASICs), programmable logic devices (PLDs), or the like, or a combination of such hardware devices.

PEDs 302 may also include a microphone 336 for receiving voice input from a passenger. The voice input can be converted into text by application 314 for processing. In another aspect, PED 302 also includes a camera 337 that may be used by a passenger to upload a video.

PED 302 includes a storage device 316 that may be or may include any storage medium for storing data in a non-volatile manner, such as one or more magnetic or optical based disks, flash memory, or solid-state drive. The storage device 316 may be used to store content displayed on display 304 of PED 302 when used by a passenger. In one aspect, display 304 may include a touch screen for receiving input commands.

The storage device 316 may also store the application 314 that is executed out of memory 310. Application 314 may be used to pair the PED 302 with the aircraft systems to receive content from device 115, as well as to communicate with CMD 360.

As an example, application 314 may be made available for download and installation via a public repository such as that maintained respectively under the trademark GOOGLE PLAY by Google, Inc. and/or the APP STORE maintained by Apple Inc. (without derogation to any third party trademark rights). In addition, application 314 may be provided for download by an airline carrier on a website or from the onboard management system 344.

In one aspect, PED 302 uses a PED communication module 308 to communicate with the seat device 326 and/or CMD 360, when installed. In one aspect, PED communication module 308 may include one or more interfaces to communicate with different devices, including Wi-Fi interface, Bluetooth interface, NFC (Near Field Communication) interface and others. The adaptive aspects described herein are not limited to any specific interface. It is noteworthy that although a single block is shown for the PED communication module 308 for convenience, the communication module may have different interface, cards, logic and circuitry to comply with the different communication protocols/standards.

Seat peripheral devices (e.g., seat device 326) for a transportation vehicle, such as monitors, seat boxes, other LRUs, etc., may be powered by an AC power supply such as the AC power supply 382. The AC power supply (e.g., AC power supply 382) supplies an AC voltage that is converted to a DC voltage to power the seat peripheral devices. For example, the AC power supply 382 may supply 115V AC, with 400/800 Hz, which is converted to 28V DC by the AC to DC converter 384 for distribution to peripheral LRUs and seat peripheral devices. The AC power supply may experience interruptions during which AC power is cut off or is not sufficiently supplied. If an interruption is a long interruption with a duration exceeding a maximum allowable duration (e.g., 200 milliseconds), then the seat peripheral devices may reboot or reinitialize. On the other hand, if an interruption is a short interruption with a duration not exceeding the maximum allowable duration, then the seat peripheral devices may not need to reboot or reinitialize. For example, in an aircraft, if an interruption of AC power does not last longer than the maximum allowable duration of 200 milliseconds, seat peripheral devices may not reboot or reinitialize during this short interruption. To allow the seat peripheral devices avoid rebooting or reinitializing during a short interruption, a seat power supply is configured to provide a backup power (e.g., 28V DC) during the short interruption (e.g., with a duration of 200 millisecond or less). A seat peripheral device may include one or more processors (e.g., processor 332) that constantly read and/or write to memory devices (e.g., memory 340) such as non-volatile memories that contain critical operational data. If a power interruption occurs without any warning, especially for a longer duration than the maximum allowable duration, then the seat peripheral device may not operate properly even after the power interruption ends and the power is restored.

In some aspects, when the AC power supply detects an interruption of the AC power, the DC voltage provided to the seat peripheral devices is dropped down to a lower interruption voltage (e.g., 24 V) for up to the maximum allowable duration (e.g., 200 milliseconds) to continue to power the seat peripheral devices for up to the maximum allowable duration. For example, during a power interruption at the AC power supply, the DC voltage may be dropped from 28 V DC to 24 V DC within 6 milliseconds and the DC voltage is supplied at 24 V DC for up to the maximum allowable duration of 200 milliseconds. The seat peripheral devices may be configured to detect the drop of the DC voltage to the lower interruption voltage (e.g., drop from 28 V DC to 24 V DC). The seat peripheral devices may use the detection of the drop of the DC voltage as an early warning indicator and thus may finish a current operation and prepare for a potential shutdown, in case the power interruption does not end and the power is not restored before the maximum allowable duration expires. If the power interruption ends and the power is restored (e.g., back to 24 V DC) before the maximum allowable duration, then the seat peripheral devices may return to their previous operation states.

In some aspects, a comparison component (e.g., comparison component 368) capable of comparing two voltage inputs may be used for the seat peripheral devices to detect the voltage drop of the DC voltage to the lower interruption voltage (e.g., drop from 28 V DC to 24 V DC). For example, to detect the voltage drop from 28 V DC to 24 V DC, the comparison component may be configured such that a first terminal of the comparison component is connected to the DC voltage and a second terminal of the comparison component is provided with a fixed reference voltage of 24 V DC, so as to compare the DC voltage and the fixed reference voltage. In this example, if the DC voltage drops below the fixed reference voltage of 24V DC, then the comparison component will be triggered and a warning indicator may be generated (e.g., to a microprocessor controlling the seat peripheral device(s)). In some examples, a comparator may be used to perform such a comparison of the DC voltage and the fixed reference voltage.

However, the above-discussed approach utilizing the comparison component with a fixed reference voltage may not provide optimal results due to various issues discussed below. One issue is that, even if an optimal supply voltage for seat peripheral devices is 28 V DC, the seat peripheral devices may not always be supplied with 28 V DC. For example, the tolerance of 28 V DC converted from the AC power is typically +/−5%, or +29.4 Vdc/+26.6 Vdc, and thus the DC voltage supplied to the seat peripheral devices may vary. The AC power supply generally has a power output rating of 400W or more, and thus it may be difficult to provide a better tolerance rating than +/−5%. With the varying DC voltages supplied to the seat peripheral devices, it may not be optimal to configure the comparison component to compare the varying DC voltages with the fixed reference voltage.

Another issue is related to varying lengths of cables between the AC power supply and various seat peripheral devices. The lengths of the cables between the AC power supply and various seat peripheral devices are not the same, and may often vary greatly. For example, a short cable may be used for one seat peripheral device that is close to the AC power supply, while a long cable may be used for another seat peripheral device that is relatively far from the AC power supply. Because a longer cable has more resistance than a shorter cable, the longer cable may cause a larger voltage drop than the shorter cable. For example, little or no voltage drop may be present when a short cable is used, while a voltage drop of several volts may be present when a long cable is used. Hence, the actual supply voltages supplied the seat peripheral devices may vary depending on the varying cable lengths to different seat peripheral devices.

Another issue is related to different seat peripheral devices having different power dissipation requirements (e.g., in addition to varying voltage drops due to varying cable lengths as mentioned above), which may cause different seat peripheral devices to draw different amounts of current. For example, different monitors with different sizes may have different power dissipation requirements, and thus each of the monitors may draw a different amount of current. Due to the varying power dissipation requirements for different seat peripheral devices, the actual supply voltage supplied to each of the seat peripheral devices may vary.

Hence, due to the varying voltage characteristics for varying cable lengths, a comparison component configured with a fixed reference voltage (e.g., 24 V DC) may not produce optimal results, depending upon a length of a cable used for a particular seat peripheral device and power supply tolerance. For example, if a long cable is used for a seat peripheral device and/or the seat peripheral device has a high power dissipation, then a comparator for the seat peripheral device will be triggered prematurely due to the voltage drop from the power supply, even if the DC voltage did not actually drop below the reference voltage. On the other hand, if a short cable is used for a seat peripheral device and/or the seat peripheral device has a low power dissipation, then a comparator for the seat peripheral device may not be triggered even if the DC voltage drops below the reference voltage and miss a low voltage condition because there is little or no voltage drop across the short cable, especially if the power supply tolerance is high.

Comparison Component Utilizing a Fixed Reference Voltage: FIG. 3B shows an example of a system for detecting a low voltage condition utilizing a fixed reference voltage, according to some aspects. As shown in FIG. 3B, an AC voltage from the AC voltage supply 382 of the power supply component 380 is first converted to a DC voltage (V_{DC}) using the AC-to-DC converter 384 of the power supply component 380. The DC voltage (V_{DC}) is supplied to a seat device 326 via the cable 386. Although the DC voltage (V_{DC}) is provided at one end of the cable 386, a supply voltage (V_{supply}) at the other end of the cable 386 that is an actual voltage supplied to the seat device 326 may be different from the DC voltage (V_{DC}).

The seat device 326 is a seat peripheral device that includes a comparison component 368A, which is an example of a comparison component 368 of FIG. 3A. The comparison component 368A includes a comparator 392 that may be powered by a comparator voltage source 394. In the example of FIG. 3B, the input voltage (Vᵢₙₚᵤₜ) into an input of the comparator is the supply voltage (V_{supply}) supplied to the seat device 326. As shown in FIG. 3B, the input voltage (Vᵢₙₚᵤₜ) is provided to a non-inverting terminal of the comparator 392 and a fixed reference voltage (V_{ref_fixed}) is provided to an inverting terminal of the comparator 392 by a reference voltage supply 396. The fixed reference voltage (V_{ref_fixed}) is a threshold indicating a power interruption at the power supply component 380. In FIG. 3B, the fixed reference voltage (V_{ref_fixed}) remains unchanged, regardless of a magnitude of the supply voltage (V_{supply}). If the input voltage (Vᵢₙₚᵤₜ) exceeds the fixed reference voltage (V_{ref_fixed}), then the comparator 392 outputs a first output voltage (e.g., high signal) as an output voltage (Vₒᵤₜₚᵤₜ) of the comparator 392. The output voltage (Vₒᵤₜₚᵤₜ) may be sent to the processor 332 (shown in FIG. 3A). If the output voltage (Vₒᵤₜₚᵤₜ) is the first output voltage, the processor 332 of the seat device 326 may continue with any operation of the seat device 326. On the other hand, if the input voltage (Vᵢₙₚᵤₜ) is less than or equal to the fixed reference voltage (V_{ref_fixed}), then the comparator 392 outputs a second output voltage (e.g., low signal) as an output voltage (Vₒᵤₜₚᵤₜ) of the comparator 392. If the output voltage (Vₒᵤₜₚᵤₜ) is the second output voltage, the processor 332 of the seat device 326 prepares the seat device 326 for a potential shutdown.

Depending on a length of the cable 386, a supply voltage (V_{supply}) at one end of the cable 386 supplied to the seat device 326 may vary, even when the DC voltage (V_{DC}) provided at the other end of the cable 386 does not vary. The fixed reference voltage (V_{ref_fixed}) is set to be compared with the DC voltage (V_{DC}), but the supply voltage (V_{supply}) that is actually compared with the fixed reference voltage (V_{ref_fixed}) may not reflect the DC voltage (V_{DC}). For example, if the length of the cable 386 is long, a large voltage drop may occur between the DC voltage (V_{DC}) and the supply voltage (V_{supply}), which may cause the supply voltage (V_{supply}) to be substantially lower than the DC voltage (V_{DC}). With such a voltage drop from the DC voltage (V_{DC}), the lower supply voltage (V_{supply}) that does not correctly reflect the DC voltage (V_{DC}) may prematurely go below the fixed reference voltage (V_{ref_fixed}) even when the DC voltage (V_{DC}) is not below the fixed reference voltage (V_{ref_fixed}), which may prematurely trigger the second output voltage for the output voltage (Vₒᵤₜₚᵤₜ) of the comparator 392. By prematurely triggering the second output voltage, the processor 332 receiving the second output voltage prematurely prepares the seat device 326 for a shutdown or reinitialization. On the other hand, if the cable 386 is short, a large voltage drop may not occur between the DC voltage (V_{DC}) and the supply voltage (V_{supply}), and thus the supply voltage (V_{supply}) may be closer to the DC voltage (V_{DC}). In this case, the supply voltage (V_{supply}) may not prematurely trigger the second output voltage for the output voltage (Vₒᵤₜₚᵤₜ) of the comparator 392.

As discussed above, if a fixed reference voltage that remains unchanged is used to compare with the supply voltage supplied to the seat peripheral device (e.g., seat device 326), the varying voltage between the DC voltage (e.g., at the power supply component 380) and the supply voltage (e.g., at the seat peripheral device such as the seat device 326) is not considered. Hence, for example, if a long cable and/or a high power dissipation causes a voltage drop from the DC voltage, the supply voltage may be substantially lower than the DC voltage and thus may prematurely go below the fixed reference voltage, which prematurely triggers the comparison component to provide an output voltage that may be used as an indicator for the processor to prepare for a potential shut down of the seat peripheral device. One approach to account for these factors may be to manually adjust a reference voltage for each seat peripheral device based on a cable length and/or a power dissipation requirement of each seat peripheral device. However, such an approach may be manually intensive and cumbersome, especially considering that numerous seat peripheral devices exist within a single transportation vehicle.

According to some aspects of the disclosure, an approach to automatically adjust a reference voltage based on a supply voltage at a seat peripheral device is provided, where the reference voltage may be used to detect a power interruption at a power supply component. As such, varying magnitudes of supply voltages for multiple seat peripheral devices with different cable lengths and/or power dissipation requirements may be automatically considered when configuring reference voltages respectively for the multiple seat peripheral devices. In particular, according to some aspects, a seat peripheral device for a transportation vehicle such as an aircraft may include a seat peripheral component coupled to a passenger seat, where the seat peripheral component includes a comparison component, a reference component, and a processor electrically coupled to the comparison component. Instead of utilizing a fixed reference voltage for all seat peripheral devices, the reference component of each seat peripheral device generates a reference voltage based on the supply voltage when the DC voltage provided by the power supply component is at or above a threshold level (e.g., with no power interruption). The reference voltage generated by the reference component is provided to the comparison component, which compares an input voltage based on the supply voltage with the reference voltage and outputs an output voltage based on the comparison. Hence, according to some aspects of the disclosure, the reference voltage is not a fixed value that remains unchanged, but is rather generated based on the supply voltage, where the supply voltage may vary depending on various factors such as a length of a cable providing the supply voltage and/or a power dissipation requirement of the seat peripheral device.

A power interruption at the power supply component will drop the DV voltage at one end of the cable below the threshold level, and thus will accordingly reduce the supply voltage at the other end of the cable. To detect the power interruption, the reference voltage should not be generated based on the supply voltage during the power interruption, but rather the reference voltage prior to the power interruption should be used. Hence, when the DC voltage drops below the threshold level to cause the supply voltage to drop during the power interruption, the reference component maintains the reference voltage at a same level as the reference voltage prior the power interruption. Therefore, even if the supply voltage decreases during the power interruption, the reference voltage prior to the power interruption is still provided to the comparison component, such that the comparison component can compare the input voltage based on the decreased supply voltage during the power interruption with the magnitude of the reference voltage prior to the power interruption.

Comparison Component Utilizing an Adjusted Reference Voltage: FIG. 3C shows an example of a system for detecting a low voltage condition within a transportation vehicle by utilizing a reference voltage generated based on a supply voltage, according to one aspect of the present disclosure. As shown in FIG. 3C, an AC voltage from the AC voltage supply 382 of the power supply component 380 is first converted to a DC voltage (V_{DC}) using the AC-to-DC converter 384 of the power supply component 380. The DC voltage (V_{DC}) is supplied to a seat device 326 via the cable 386. As discussed above, although the DC voltage (V_{DC}) is provided at one end of the cable 386, an actual voltage supplied to the seat device 326 at the other end of the cable 386, a supply voltage (V_{supply}), may be different from the DC voltage (V_{DC}). In an aspect, the supply voltage (V_{supply}) may be a function of the DC voltage (V_{DC}) and a length of the cable 386 between the power supply component 380 and the seat device 326. For example, the cable 386 with a longer length may cause the supply voltage (V_{supply}) to decrease more from the DC voltage (V_{DC}). Further, in an aspect, the supply voltage (V_{supply}) may be a function of the DC voltage (V_{DC}), a length of the cable 386, and a power dissipation requirement of the seat device 326. For example, a seat device with a higher power dissipation may cause the supply voltage (V_{supply}) to decrease more from the DC voltage (V_{DC}).

The seat device 326 is a seat peripheral device that includes a seat peripheral component 367 coupled to a passenger seat of a transportation vehicle such as an aircraft. The seat peripheral component 367 includes a comparison component 368B, which is an example of a comparison component 368 of FIG. 3A according to some aspects of the disclosure. The comparison component 368B is configured to compare an input voltage (Vᵢₙₚᵤₜ) and a reference voltage (V_{ref}) associated with the power supply component 380, where the input voltage (Vᵢₙₚᵤₜ) is based on the supply voltage (V_{supply}). For example, the comparison component 368B may reduce the supply voltage (V_{supply}) to the input voltage (Vᵢₙₚᵤₜ) that is lower than the supply voltage (V_{supply}) because a comparing unit (e.g., comparator) for comparing the input voltage (Vᵢₙₚᵤₜ) and the reference voltage (V_{ref}) may not be configured to directly take the supply voltage (V_{supply}). As shown in FIG. 3C, the input voltage (Vᵢₙₚᵤₜ) may be provided to an input voltage terminal tᵢₙₚᵤₜ and the reference voltage (V_{ref}) may be provided to a reference terminal t_{ref} in the comparison component 368B, which compares the input voltage (Vᵢₙₚᵤₜ) and the reference voltage (V_{ref}) and then outputs a result of the comparison as an output voltage (Vₒᵤₜₚᵤₜ). The output voltage (Vₒᵤₜₚᵤₜ) may be provided to the processor 332.

The reference voltage (V_{ref}) is a threshold indicating a power interruption at the power supply component 380. If the input voltage (Vᵢₙₚᵤₜ) exceeds the reference voltage (V_{ref}), then the comparison component 368B outputs a first output voltage (e.g., high signal) as the output voltage (Vₒᵤₜₚᵤₜ) of the comparison component 368B. The first output voltage indicates no power interruption at the power supply component 380. Hence, if the output voltage (Vₒᵤₜₚᵤₜ) is the first output voltage, the processor 332 of the seat device 326 may continue with any operation of the seat device 326. On the other hand, if the input voltage (Vᵢₙₚᵤₜ) is less than or equal to the reference voltage (V_{ref}), then the comparison component 368B outputs a second output voltage (e.g., low signal or zero voltage) as the output voltage (Vₒᵤₜₚᵤₜ) of the comparison component 368B. The second output voltage indicates a power interruption at the power supply component 380. Hence, if the output voltage (Vₒᵤₜₚᵤₜ) is the second output voltage, the processor 332 of the seat device 326 prepare the seat device 326 for a potential shutdown.

As shown in FIG. 3C, according to some aspects of the disclosure, the reference voltage (V_{ref}) is not a fixed value that remains the same. In particular, the reference voltage (V_{ref}) according to some aspects of the disclosure may vary depending on the magnitude of the supply voltage (V_{supply}) that may vary depending on the length of the cable 386 and/or a power dissipation requirement of the seat device 326. The seat peripheral component 367 includes a reference component 370, which generates and provides the reference voltage (V_{ref}) to the comparison component 368B. The reference component 370 generates the reference voltage (V_{ref}) based on the supply voltage (V_{supply}) if the DC voltage provided by the power supply component 380 is at or above a threshold level (e.g., with no power interruption). For example, when the power supply component 380 provides sufficient power (e.g., with no power interruption) at or above the threshold level, the reference component 370 generates the reference voltage (V_{ref}) based on the supply voltage (V_{supply}). Utilizing the reference voltage (V_{ref}) based on the supply voltage (V_{supply}) takes into account the supply voltage (V_{supply}) varying depending on the length of the cable 386 and/or a power dissipation requirement of the seat device 326. Because the reference voltage (V_{ref}) is based on the supply voltage (V_{supply}), the variation of the supply voltage (V_{supply}) depending on the length of the cable 386 and/or the power dissipation requirement is properly considered when generating the reference voltage (V_{ref}). As such, even if the supply voltage (V_{supply}) does not correctly reflect the DC voltage (V_{DC}), the input voltage (Vᵢₙₚᵤₜ) based on the voltage (V_{supply}) does not prematurely go below the reference voltage (V_{ref}), and thus does not prematurely trigger the second output voltage for the output voltage (Vₒᵤₜₚᵤₜ) of the comparator 392. Hence, a premature preparation for a shutdown or a reinitialization (e.g., based on a premature trigger of the second output voltage) may be prevented.

If the DC voltage (V_{DC}) drops below the threshold level during the power interruption to cause the supply voltage to drop, the reference component 370 is configured to maintain the reference voltage (V_{ref}) at a same level as the reference voltage (V_{ref}) prior the power interruption. For example, when the power supply component 380 provides insufficient power (e.g., due to a power interruption) below the threshold level, this causes the supply voltage (V_{supply}) to decrease to an undesirable level. Such a decrease in the supply voltage (V_{supply}) during this low power condition (e.g., during the power interruption) should not affect the reference voltage (V_{ref}) because the reference voltage (V_{ref}) is used to detect the low power condition such as the power interruption. Therefore, according to some aspects of the disclosure, the reference voltage (V_{ref}) is maintained at the same level as the reference voltage prior the power interruption, if the DC voltage (V_{DC}) drops below the threshold level to cause the supply voltage to drop during the power interruption. Hence, for example, the magnitude of the supply voltage (V_{supply}) with no power interruption at the power supply component 380 may be used as a basis for generating the reference voltage (V_{ref}) and is maintained during a power interruption, while the magnitude of the supply voltage (V_{supply}) during the power interruption is not used for generating the reference voltage (V_{ref}).

In an aspect, the reference component 370 may be configured to provide the reference voltage (V_{ref}) such that the input voltage (Vᵢₙₚᵤₜ) based on the supply voltage (V_{supply}) exceeds the reference voltage (V_{ref}) if the DC voltage (V_{DC}) is at or above the threshold level (e.g., with no power interruption), while the input voltage (Vᵢₙₚᵤₜ) based on the supply voltage (V_{supply}) is less than or equal to the reference voltage (V_{ref}) if the DC voltage (V_{DC}) drops below the threshold level during the power interruption. As such, when the reference voltage (V_{ref}) is generated based on the supply voltage (V_{supply}) with no power interruption or is maintained at this level prior to a power interruption, the reference voltage (V_{ref}) being compared with the supply voltage (V_{supply}) may reflect the threshold level being compared with the DC voltage (V_{DC}).

If the input voltage (Vᵢₙₚᵤₜ) exceeds the reference voltage (V_{ref}), then the comparator 392 outputs a first output voltage (e.g., high signal) as an output voltage (Vₒᵤₜₚᵤₜ) of the comparator 392. If the output voltage (Vₒᵤₜₚᵤₜ) is the first output voltage, the processor 332 (shown in FIG. 3A) of the seat device 326 may continue with any operation of the seat device 326. On the other hand, if the input voltage (Vᵢₙₚᵤₜ) is less than or equal to the reference voltage (V_{ref}), then the comparator 392 outputs a second output voltage (e.g., a low signal or zero voltage) as an output voltage (Vₒᵤₜₚᵤₜ) of the comparator 392. If the output voltage (Vₒᵤₜₚᵤₜ) is the first output voltage, the processor 332 of the seat device 326 prepare the seat device 326 for a potential shutdown or reinitialization of the seat device 326.

In an aspect, the reference component 370 may include a first transistor component 371 and a second transistor component 372. The first transistor component 371 may include a first transistor that is deactivated if the DC voltage (V_{DC}) drops below the threshold level which causes the supply voltage (V_{supply}) to drop. The second transistor component 372 may include a second transistor that is deactivated, to maintain the reference voltage (V_{ref}), by the second output voltage from the comparison component 368B if the DC voltage (V_{DC}) drops below the threshold level which causes the supply voltage (V_{supply}) to drop to reduce the input voltage(Vᵢₙₚᵤₜ). As discussed above, the second output voltage is output in response to the input voltage (Vᵢₙₚᵤₜ) being less than or equal to the reference voltage (V_{ref}). In an aspect, the first transistor may be a first Negative-Positive-Negative (NPN) transistor, and the second transistor may be a second NPN transistor.

In some aspects, the first transistor may include a first collector directly connected to a node receiving the supply voltage (V_{supply}), a first base connected to the node receiving the supply voltage (V_{supply}) via at least one resistor that causes a base voltage at the first base to be lower than the supply voltage, and a first emitter connected to a reference terminal t_{ref} of the comparison component 368B that receives the reference voltage (V_{ref}). In some aspects, the second transistor may include a second collector connected to the reference terminal t_{ref}, a second base directly connected to an output of the comparison component 368B, and a second emitter connected to the ground.

In an aspect, the second transistor component 372 may further include a maintenance capacitor positioned parallel to the second transistor. In this aspect, the second transistor component 372 may be configured to maintain the reference voltage (V_{ref}) at the same level as the reference voltage (V_{ref}) prior the power interruption using the maintenance capacitor while the second transistor is deactivated when the DC voltage (V_{DC}) dropping below the threshold level causes the supply voltage (V_{supply}) to drop.

In an aspect, optionally, the seat peripheral component 367 may further include an initialization component 374 configured to maintain the output voltage (Vₒᵤₜ) of the comparison component 368B as the second output voltage (e.g., low signal or zero voltage) during initialization of the seat device 326. When the seat device 326 is first powered on and is in an initialization stage during the power-on process, an incorrect reference voltage (V_{ref}) may be generated during this process and/or the supply voltage (V_{supply}) may not be at a stable state and/or may be abnormally low during this process. Hence, during the initialization of the seat device 326, it may be beneficial to maintain the output voltage (Vₒᵤₜ) of the comparison component 368B as the second output voltage.

Circuit Illustration for Example Implementation 1: FIG. 3D shows an example system with a circuit diagram of various components for detecting a low voltage condition within a transportation vehicle by utilizing a reference voltage generated based on a supply voltage, according to an aspect of the present disclosure. The example shown in FIG. 3D may be perceived as an example of the components shown in FIG. 3C. In particular, FIG. 3D shows an example circuit diagram of the seat device 326 with the seat peripheral component 367 having the comparison component 368C, the reference component 370C, and the processor 332. The comparison component 368C and the reference component 370C are examples of the comparison component 368B and the reference component 370 of FIG. 3C. Further, as shown in FIG. 3D, an AC voltage from the AC voltage supply 382 of the power supply component 380 is first converted to a DC voltage (V_{DC}) using the AC-to-DC converter 384 of the power supply component 380. The DC voltage (V_{DC}) is supplied to a seat device 326 via the cable 386.

In the example shown in FIG. 3D, the comparison component 368C may include a comparator U1, a first voltage source VS1, a first resistor R1, a second resistor R2, and a first capacitor C1. In an example, the first voltage source VS1 may provide 28 V, a first resistor R1 may be 22 kOhms, the second resistor R2 may be 220 kOhms, and the first capacitor C1 may be 0.1 microfarad. The first resistor R1 and the second resistor R2 reduce a maximum voltage of the supply voltage (V_{supply}) to provide the input voltage (Vᵢₙₚᵤₜ), because the comparator U1 does not support a rail-to-rail operation for the supply voltage (V_{supply}). Hence, the input voltage (Vᵢₙₚᵤₜ) is based on the supply voltage (V_{supply}). The comparator U1 is powered by the first voltage source VS1. A first end of the first resistor R1 is connected to a node receiving the supply voltage (V_{supply}) and a second end of the first resistor R1 is connected to a non-inverting terminal of the comparator U1 to provide the input voltage (Vᵢₙₚᵤₜ). Because the input voltage (Vᵢₙₚᵤₜ) is provided to the non-inverting terminal of the comparator U1, the non-inverting terminal of the comparator U1 may also be referred to as an input voltage terminal. The second end of the first resistor R1 is also connected to a first end of the second resistor R2, where a second end of the second resistor R2 is connected to the ground. Further, the second end of the first resistor R1 may be connected to a first end of the first capacitor C1, which is connected to the ground at its second end. The reference voltage (V_{ref}) is provided to an inverting terminal of the comparator U1 by the reference component 370C, which is described in more detail below. Because the reference voltage (V_{ref}) is provided to the inverting terminal of the comparator U1, the inverting terminal of the comparator U1 may also be referred to as a reference terminal.

The first capacitor C1 may be implemented to provide additional filtering for the supply voltage (V_{supply}) because the cable 386 may inject unwanted noise and/or glitches especially if the cable 386 is long. The first capacitor C1 can prevent the external noise and/or glitches from erroneously affecting the output of the comparator U1.

If the input voltage (Vᵢₙₚᵤₜ) exceeds the reference voltage (V_{ref}), then the comparator U1 outputs a first output voltage (e.g., high signal) as the output voltage (Vₒᵤₜₚᵤₜ) of the comparison component 368C, where the first output voltage indicates no power interruption at the power supply component 380. On the other hand, if the input voltage (Vᵢₙₚᵤₜ) is less than or equal to the reference voltage (V_{ref}), then the comparator U1 outputs a second output voltage (e.g., low signal or zero voltage) as an output voltage (Vₒᵤₜₚᵤₜ) of the comparison component 368C, where the second output voltage indicates a power interruption at the power supply component 380.

In the example shown in FIG. 3D, the reference component 370C includes the first transistor component 371C and the second transistor component 372C. The first transistor component 371C and the second transistor component 372C are examples of the first transistor component 371B and the second transistor component 372B of FIG. 3C. The first transistor component 371C includes a third resistor R3, a fourth resistor R 4, and a first transistor T 1. In an example, the third resistor R3 may be 39 kOhms and the fourth resistor R 4 may be 220 kOhms. A first end of the third resistor R3 is connected to receive the supply voltage (V_{supply}) and a second end of the third resistor R3 is connected to a base of the first transistor T1 and to a first end of the fourth resistor R4 that is connected to the ground at its second end. A collector of the first transistor T1 is directly connected to the supply voltage (V_{supply}), and an emitter of the first transistor T1 is connected to the second transistor component 372C. The third resistor R 3 and the fourth resistor R 4 are used to reduce the supply voltage (V_{supply}) to a lower voltage at the base of the first transistor T1. As such, the base-emitter voltage V_{be} of the first transistor T1 is lower than the supply voltage (V_{supply}) when the DC voltage (V_{DC}) is at or above the threshold (e.g., with no power interruption).

The second transistor component 372C includes a fifth resistor R 5, a sixth resistor R6, a seventh resistor R7, an eighth resistor R8, a maintenance capacitor Cm, and a second transistor T2. In an example, the fifth resistor R5 may be 200 Ohms, the sixth resistor R6 may be 2 megaOhms, the seventh resistor R7 may be 10 kOhms, the eighth resistor R8 may be 10 kOhms, and the maintenance capacitor Cm may be 10 microfarad. A first end of the fifth resistor R5 is connected to the emitter of the first transistor T1 of the first transistor component 371C and a second end of the fifth resistor R5 is connected to the reference terminal (e.g., non-inverting terminal) of the comparator U1 to provide the reference voltage (V_{ref}) to the comparator U1. Hence, the reference voltage (V_{ref}) is generated based at least on the third resistor R3, the fourth resistor R4, and the fifth resistor R5 as well as the supply voltage (V_{supply}), when there is no power interruption. The second end of the fifth resistor R5 is also connected to a first end of the maintenance capacitor Cm, which is connected to the ground at its second end, and is further connected to a first end of the sixth resistor R6, which is connected to a collector of the second transistor T2. An emitter of the second transistor T2 is connected to the ground, and a base of the second transistor T2 is connected to a first end of the seventh resistor R7, which is connected to the output of the comparator U1 at its second end. The base of the second resistor T2 is also connected to the first end of the eight resistor R8, which is connected to the ground at its second end.

When there is no power interruption, the maintenance capacitor Cm is charged with the reference voltage (V_{ref}). Further, when there is no power interruption, the voltage output (Vₒᵤₜ) will be a high signal, and thus will cause the second transistor T2 to turn on, which allows the second end of the sixth resistor R6 to be connected to the ground. With the sixth resistor R6 connected to the ground via the second transistor T2, the sixth resistor R6 slowly drains the maintenance capacitor Cm, which allows the reference voltage (V_{ref}) to be adjusted based on the supply voltage (V_{supply}) when the supply voltage (V_{supply}) varies with no power interruption.

With a power interruption, the DC voltage (V_{DC}) may drop below the threshold level, which will also cause the supply voltage (V_{supply}) to drop accordingly. For example, when the power interruption occurs, the DC voltage (V_{DC}) may quickly (e.g., within 6 milliseconds) drop from 28 V to 24 V, where the threshold level may be set to 25 V. With the drop in the supply voltage (V_{supply}) caused by the DC voltage (V_{DC}) dropping below the threshold level, the first transistor T1 is reverse biased and is deactivated, and thus the reduced supply voltage (V_{supply}) during this lower power condition (e.g., power interruption) is not used to generate the reference voltage (V_{ref}). Hence, the reference voltage (V_{ref}) stays at the same level prior to the power interruption, which is the level of the reference voltage (V_{ref}) generated when the power supply component 380 is operating properly to provide the DC voltage (V_{DC}) at or above the threshold level (e.g., at or around 28 V). With the power interruption, while the reference voltage (V_{ref}) is maintained at the level prior to the power interruption, the drop in the supply voltage (V_{supply}) causes the input voltage (Vᵢₙₚᵤₜ) to drop below the reference voltage (V_{ref}), which causes the comparator U1 to output the second output voltage being a low signal as the output voltage (Vₒᵤₜ). As discussed above, the second signal as the output voltage (Vₒᵤₜ) of the comparator U1 indicates a low voltage condition such as the power interruption. When the DC voltage drops below the threshold level to cause the output voltage (Vₒᵤₜ) to be the low signal, the second transistor T2 is deactivated by the low signal, which causes the sixth resistor R6 to have no effect on the circuit. This prevents the voltage at the maintenance capacitor Cm from leaking through the sixth resistor R6 while the second transistor T2 is turned off, such that the maintenance capacitor Cm can provide the reference voltage (V_{ref}) at the same level prior to the power interruption. For example, during the power interruption, when the second transistor T2 is turned off, the maintenance capacitor Cm may be slowly discharged to provide the reference voltage (V_{ref}) at the same level prior to the power interruption.

In an aspect, a ninth resistor R9 connected to a second voltage source VS2 in series may be connected to the output of the comparator U1. The output of the comparator U1 may not switch to a high signal on its own without an external pull-up resistor, and thus the ninth resistor R9 is implemented as a pull-up resistor. The second voltage source VS2 is a power supply for a processor input/output bus, and thus a combination of the ninth resistor R9 and the second voltage source VS2 can “pull” the output of U1 to a correct high level that the processor 332 can recognize.

Circuit Illustration for Example Implementation 1: FIG. 3E shows another example system with a circuit diagram of various components for detecting a low voltage condition within a transportation vehicle by utilizing a reference voltage generated based on a supply voltage, according to an aspect of the present disclosure. The example shown in FIG. 3E may be perceived as an example of the components shown in FIG. 3C. In particular, FIG. 3E shows an example circuit diagram of the seat device 326 with the seat peripheral component 367 having a comparison component 368D, a reference component 370D, an initialization component 374D, and the processor 332. The comparison component 368D, the reference component 370D, and the initialization component 374D are examples of the comparison component 368B, the reference component 370, and the initialization component 374 of FIG. 3C. Further, as shown in FIG. 3E, an AC voltage from the AC voltage supply 382 of the power supply component 380 is first converted to a DC voltage (V_{DC}) using the AC-to-DC converter 384 of the power supply component 380. The DC voltage (V_{DC}) is supplied to a seat device 326 via the cable 386.

In the example shown in FIG. 3E, the comparison component 368D may include the comparator U1, the first voltage source VS1, the first resistor R1, and the second resistor R2. The example circuit for the comparison component 368D is similar to the example circuit for the comparison component 368C of FIG. 3D. Further, in FIG. 3E, the reference component 370D includes the first transistor component 371D and the second transistor component 372D, where the first transistor component 371D includes the third resistor R3, the fourth resistor R4, and the first transistor T1, and the second transistor component 372D includes the fifth resistor R5, the sixth resistor R6, the seventh resistor R7, and the eighth resistor R8, the maintenance capacitor Cm, and the second transistor T2. The example circuit for the reference component 370D is identical to the example circuit for the reference component 370C of FIG. 3D. Because the circuits of the comparison component 368D and the reference component 370D are identical to the circuits of the comparison component 368C and the reference component 370C of FIG. 3D, the operations of the comparison component 368D and the reference component 370D are similar to the operations of the comparison component 368C and the reference component 370C of FIG. 3D. Therefore, detailed explanations about the comparison component 368D and the reference component 370D are omitted for brevity.

One difference between the example of FIG. 3D and the example of FIG. 3E is that the seat peripheral component 367 of Figure E includes the initialization component 374D. The initialization component 374D includes a tenth resistor R10, an eleventh resistor R11, a twelfth resistor R12, a diode Z, and a second comparator U2. In an example, the tenth resistor R10 may be 100 kOhms, the eleventh resistor R11 may be 20 kOhms, and the twelfth resistor R12 may be 10 kOhms. A first end of the tenth resistor R10 is connected to the supply voltage (V_{supply}), while a second end of the tenth resistor R10 is connected to a non-inverting terminal of the second comparator U2. The second end of the tenth resistor R10 is also connected to a first end of the eleventh resistor R11, which is connected to the ground at its second end. A first end of the twelfth resistor R12 is connected to the supply voltage (V_{supply}), while a second end of the twelfth resistor R12 is connected to an inverting terminal of the second comparator U2. The second end of the twelfth resistor R12 is also connected to a cathode end of the diode Z, while an anode end of the diode Z is connected to the ground. In an aspect, the diode Z may be a Zener diode. The second comparator U2 is powered by the first voltage source VS1. One end of a second capacitor C2 may be connected to a node between the first voltage source VS1 and the second comparator U2, while the other end of the second capacitor C2 may be connected to the ground. The second capacitor C2 may be a decoupling bypass capacitor to provide noise filtering for the first voltage source VS1.

When the seat device 326 is first powered on and is in an initialization stage during the power-on process, the maintenance capacitor Cm may not be sufficiently charged, which may provide an incorrect reference voltage (V_{ref}) until the maintenance capacitor Cm is sufficiently charged. Further, during the initialization stage, the supply voltage (V_{supply}) may not be at a stable state and/or may be lower (e.g., at 20 V or less) than when the seat device 326 is completely powered on. Hence, during the initialization of the seat device 326, the second comparator U2 is used to maintain the output voltage (Vₒᵤₜ) to the second output voltage (e.g., low signal). After the initialization of the seat device 326, the output from the second comparator U2 will no longer cause the output voltage (Vₒᵤₜ) to become the second output voltage (e.g., low signal). It is noted that the second output voltage (e.g., low signal) may not cause the processor 306 to perform any action because the processor 306 may not be able to perform normally during the initialization stage.

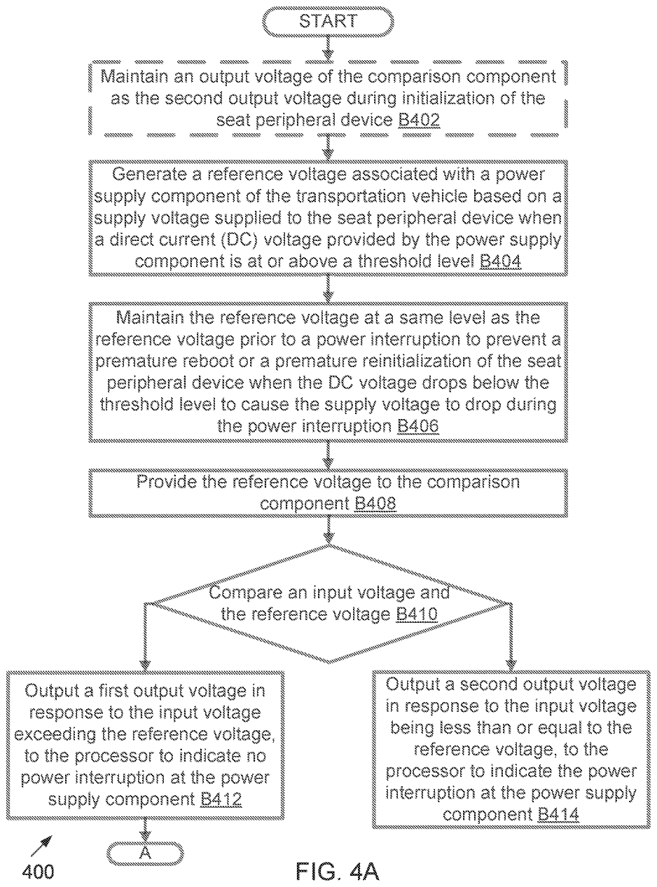

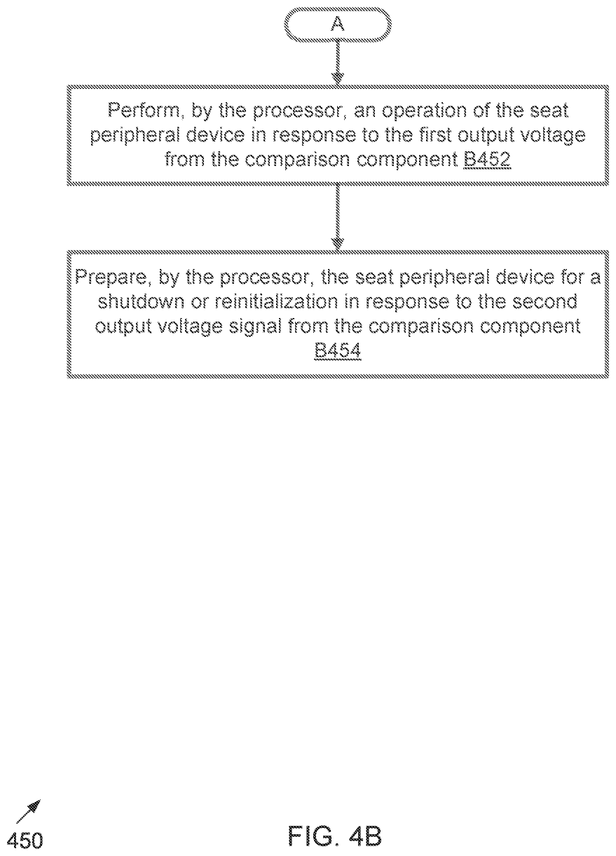

Process Flow: FIG. 4A shows a process 400 for detecting a low voltage condition at a seat peripheral device for a transportation vehicle using a seat peripheral component coupled to a passenger seat, according to one aspect of the present disclosure. The seat peripheral device may be the seat device 326 of FIGS. 3A, 3C, and 3D and may be referred to as the seat device 326. The seat peripheral component may be the seat peripheral component 367 of FIGS. 3C and 3D and may be referred to as the seat peripheral component 367. As discussed above, the seat peripheral component 367 includes the comparison component 368, the reference component 370, and the processor 332 electrically coupled to the comparison component 368.

In an aspect, in block B402, the seat device 326 may maintain (e.g., by the initialization component 374) an output voltage of the comparison component 368 as the second output voltage during initialization of the seat device 326. As shown in FIG. 3C, the seat peripheral component 367 may optionally include the initialization component 374 configured to maintain the output voltage (Vₒᵤₜ) of the comparison component 368B as the second output voltage (e.g., low signal or zero voltage) during initialization of the seat device 326. As discussed above, during the initialization of the seat device 326, it may be beneficial to maintain the output voltage (Vₒᵤₜ) of the comparison component 368B as the second output voltage because the reference voltage (V_{ref}) generated during this process and/or the supply voltage (V_{supply}) supplied during this process may not provide reliable results.

In block B404, the seat device 326 generates (e.g., by the reference component 370) a reference voltage associated with the power supply component 380 of the transportation vehicle based on a supply voltage supplied to the seat device 326 when a DC voltage provided by the power supply component 380 is at or above a threshold level. As shown in FIG. 3C, the reference component 370 generates the reference voltage (V_{ref}) based on the supply voltage (V_{supply}) if the DC voltage provided by the power supply component 380 is at or above a threshold level (e.g., with no power interruption).

In block B406, the seat device 326 maintains (e.g., by the reference component 370) the reference voltage at a same level as the reference voltage prior to a power interruption to prevent a premature reboot or a premature reinitialization of the seat device 326 when the DC voltage drops below the threshold level to cause the supply voltage to drop during the power interruption. As shown in FIG. 3C, if the DC voltage (V_{DC}) drops below the threshold level during the power interruption to cause the supply voltage to drop, the reference component 370 is configured to maintain the reference voltage (V_{ref}) at a same level as the reference voltage (V_{ref}) prior the power interruption.

In block B408, the seat device 326 provides (e.g., by the reference component 370) the reference voltage to the comparison component 368. As shown in FIG. 3C, the reference component 370 provides the reference voltage (V_{ref}) to the comparison component 368.

In block B410, the seat device 326 compares (e.g., by the comparison component 368) an input voltage and the reference voltage, where the input voltage is based on the supply voltage. As shown in FIG. 3C, the comparison component 368B is configured to compare an input voltage (Vᵢₙₚᵤₜ) and a reference voltage (V_{ref}) associated with the power supply component 380, where the input voltage (Vᵢₙₚᵤₜ) is based on the supply voltage (V_{supply}).

Based on the comparison in block B410, if the input voltage exceeds the reference voltage, the process proceeds to block B412. In block B412, the seat device 326 outputs (e.g., by the comparison component 368) a first output voltage in response to the input voltage exceeding the reference voltage, to the processor 332 to indicate no power interruption at the power supply component 380. As discussed above in reference to FIG. 3C, if the input voltage (Vᵢₙₚᵤₜ) exceeds the reference voltage (V_{ref}), then the comparison component 368B outputs a first output voltage (e.g., high signal) as the output voltage (Vₒᵤₜₚᵤₜ) of the comparison component 368B. In an aspect, additional processes may be performed after block B412, as discussed below in reference to FIG. 4B.

Based on the comparison in block B410, if the input voltage is less than or equal to the reference voltage, the process proceeds to block B414. In block B414, the seat device 326 outputs (e.g., by the comparison component 368) a second output voltage in response to the input voltage being less than or equal to the reference voltage, to the processor 332 to indicate the power interruption at the power supply component 380. As discussed above in reference to FIG. 3C, if the input voltage (Vᵢₙₚᵤₜ) is less than or equal to the reference voltage (V_{ref}), then the comparison component 368B outputs a second output voltage (e.g., low signal or zero voltage) as the output voltage (Vₒᵤₜₚᵤₜ) of the comparison component 368B.

In an aspect, the cable 386 may include a first end connected to the power supply component 380 providing the DC voltage to the cable 386 and a second end connected to the seat device 326 to supply the supply voltage, where the supply voltage is a function of the DC voltage and a length of the cable 386 between the power supply component 380 and the seat device 326. For example, as discussed above in reference to FIG. 3C, the cable 386 with a longer length may cause the supply voltage (V_{supply}) to decrease more from the DC voltage (V_{DC}). In an aspect, the supply voltage may be a function of the DC voltage, the length of the cable 386, and a power dissipation requirement of the seat device 326. For example, as discussed above in reference to FIG. 3C, a seat device with a higher power dissipation may cause the supply voltage (V_{supply}) to decrease more from the DC voltage (V_{DC}).

In an aspect, the input voltage based on the supply voltage exceeds the reference voltage when the DC voltage is at or above the threshold level, and the input voltage based on the supply voltage is less than or equal to the reference voltage when the DC voltage drops below the threshold level during the power interruption. When the reference component 370 generates the reference voltage (V_{ref}) based on the supply voltage (V_{supply}) with no power interruption or maintains at this level prior to a power interruption, the reference voltage (V_{ref}) being compared with the supply voltage (V_{supply}) may reflect the threshold level being compared with the DC voltage (V_{DC}).

In an aspect, the reference component 370 may include a first transistor component including a first transistor that is deactivated when the DC voltage drops below the threshold level which causes the supply voltage to drop, and a second transistor component including a second transistor that is deactivated, to maintain the reference voltage, by the second output voltage from the comparison component 368 in response to the input voltage being less than or equal to the reference voltage when the DC voltage drops below the threshold level which causes the supply voltage to drop to reduce the input voltage. In an aspect, the first transistor may be a first NPN transistor, and the second transistor may be a second NPN transistor. In an aspect, the second transistor component further includes a maintenance capacitor positioned parallel to the second transistor, where the second transistor component is configured to maintain the reference voltage at the same level as the reference voltage prior the power interruption using the maintenance capacitor while the second transistor is deactivated when the DC voltage dropping below the threshold level causes the supply voltage to drop. In an aspect, the first transistor includes a first collector directly connected to a node receiving the supply voltage, a first base connected to the node receiving the supply voltage via at least one resistor that causes a base voltage at the first base to be lower than the supply voltage, and a first emitter connected to a reference terminal of the comparison component 368 that receives the reference voltage, and the second transistor includes a second collector connected to the reference terminal, a second base directly connected to an output of the comparison component 368, and a second emitter connected to a ground.

As discussed above in reference to FIG. 3D, with the drop in the supply voltage (V_{supply}) caused by the DC voltage (V_{DC}) dropping below the threshold level, the first transistor T1 is reverse biased and is deactivated, and thus the reduced supply voltage (V_{supply}) during this lower power condition (e.g., power interruption) is not used to generate the reference voltage (V_{ref}). Further, with the power interruption, while the reference voltage (V_{ref}) is maintained at the level prior to the power interruption, the drop in the supply voltage (V_{supply}) causes the input voltage (Vᵢₙₚᵤₜ) to drop below the reference voltage (V_{ref}), which causes the comparator U1 to output the second output voltage being a low signal as the output voltage (Vₒᵤₜ). This low signal deactivates the second transistor T2, causing the sixth resistor R6 to have no effect on the circuit, which prevents the voltage at the maintenance capacitor Cm from leaking through the sixth resistor R6 while the second transistor T2 is turned off, such that the maintenance capacitor Cm can provide the reference voltage (V_{ref}) at the same level prior to the power interruption.

FIG. 4B shows a process 450 for detecting a low voltage condition at a seat peripheral device for a transportation vehicle using a seat peripheral component coupled to a passenger seat, continuing from the process 400 of FIG. 4A, according to one aspect of the present disclosure.

In block B452, the seat device 326 performs (e.g., by the processor 332) an operation of the seat device 326 in response to the first output voltage from the comparison component 368. Block B452 may take place after Block B412 of FIG. 4A. As discussed above in reference to FIG. 3C, if the output voltage (Vₒᵤₜₚᵤₜ) is the first output voltage, the processor 332 of the seat device 326 may continue with any operation of the seat device 326.

In block B454, the seat device 326 prepares (e.g., by the processor 332) the seat device 326 for a shutdown or reinitialization in response to the second output voltage signal from the comparison component 368. As discussed above in reference to FIG. 3C, if the output voltage (Vₒᵤₜₚᵤₜ) is the second output voltage, the processor 332 of the seat device 326 prepare the seat device 326 for a potential shutdown

Accordingly, various aspects of the present disclosure provide a reference voltage that is generated based on the supply voltage instead of utilizing a fixed reference voltage, such that various factors that may affect voltage changes between the DC voltage provided by the power supply component and the supply voltage are considered. For example, because the length of the cable between the power supply component and the supply voltage and/or a power dissipation requirement of each seat peripheral device may cause the supply voltage to be lower than the DC voltage, the reference voltage based on the supply voltage may be utilized to consider the voltage changes between the DC voltage and the supply voltage.

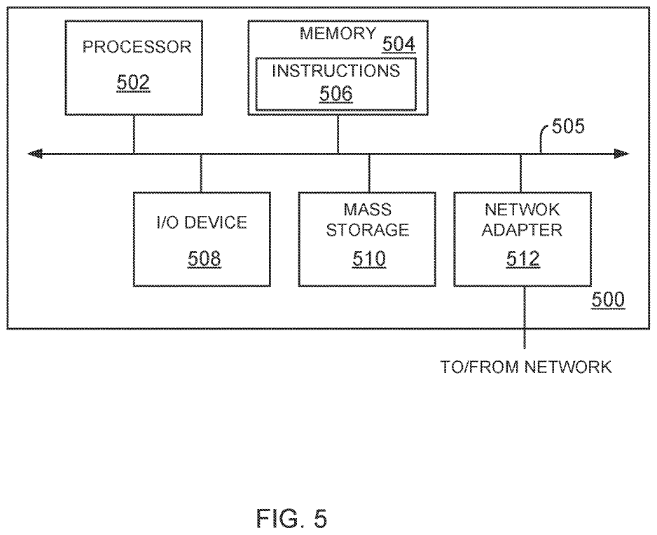

Processing System: FIG. 5 is a high-level block diagram showing an example of the architecture of a processing system 500 that may be used according to one aspect. The processing system 500 can represent CMD 360, media server 112, computing system 106/107, WAP 130, onboard management system 344, seat device 326 or any user device (PED 302) that attempts to interface with a vehicle computing device. Note that certain standard and well-known components which are not germane to the present aspects are not shown in FIG. 5.

The processing system 500 includes one or more processor(s) 502 and memory 504, coupled to a bus system 505. The bus system 505 shown in FIG. 5 is an abstraction that represents any one or more separate physical buses and/or point-to-point connections, connected by appropriate bridges, adapters and/or controllers. The bus system 505, therefore, may include, for example, a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (sometimes referred to as “Firewire”) or any other interconnect type.

The processor(s) 502 are the central processing units (CPUs) of the processing system 500 and, thus, control its overall operation. In certain aspects, the processors 502 accomplish this by executing software stored in memory 504. A processor 502 may be, or may include, one or more programmable general-purpose or special-purpose microprocessors, digital signal processors (DSPs), programmable controllers, application specific integrated circuits (ASICs), programmable logic devices (PLDs), or the like, or a combination of such devices.

Memory 504 represents any form of random-access memory (RAM), read-only memory (ROM), flash memory, or the like, or a combination of such devices. Memory 504 includes the main memory of the processing system 500. Instructions 506 may be used to the process steps of FIGS. 4A-4B executed by the comparison component 368, the reference component 370, the processor 332, CMI 320, described above.

Also connected to the processors 502 through the bus system 505 are one or more internal mass storage devices 510, and a network adapter 512. Internal mass storage devices 510 may be or may include any conventional medium for storing large volumes of data in a non-volatile manner, such as one or more magnetic or optical based disks, flash memory, or solid-state drive.

The network adapter 512 provides the processing system 500 with the ability to communicate with remote devices (e.g., over a network) and may be, for example, an Ethernet adapter or the like.

The processing system 500 also includes one or more input/output (I/O) devices 508 coupled to the bus system 505. The I/O devices 508 may include, for example, a display device, a keyboard, a mouse, etc. The I/O device may be in the form of a handset having one or more of the foregoing components, such as a display with a real or virtual keyboard, buttons, and/or other touch-sensitive surfaces.

Thus, methods and systems for detecting a low voltage condition at a seat peripheral device for a transportation vehicle using a seat peripheral component coupled to a passenger seat have been described. Note that references throughout this specification to “one aspect” (or “embodiment”) or “an aspect” mean that a particular feature, structure or characteristic described in connection with the aspect is included in at least one aspect of the present disclosure. Therefore, it is emphasized and should be appreciated that two or more references to “an aspect” or “one aspect” or “an alternative aspect” in various portions of this specification are not necessarily all referring to the same aspect. Furthermore, the particular features, structures or characteristics being referred to may be combined as suitable in one or more aspects of the disclosure, as will be recognized by those of ordinary skill in the art.

While the present disclosure is described above with respect to what is currently considered its preferred aspects, it is to be understood that the disclosure is not limited to that described above. To the contrary, the disclosure is intended to cover various modifications and equivalent arrangements within the spirit and scope of the appended claims.

What is claimed is:

1. A seat peripheral device for a transportation vehicle, comprising:
a seat peripheral component coupled to a passenger seat, the seat peripheral component comprising a comparison component, a reference component, and a processor electrically coupled to the comparison component,
wherein the comparison component configured to:
compare an input voltage and a reference voltage associated with a power supply component of the transportation vehicle, wherein the input voltage is based on a supply voltage supplied to the seat peripheral device via a cable connected to the power supply component configured to provide a direct current (DC) voltage to the cable,
output a first output voltage in response to the input voltage exceeding the reference voltage to the processor to indicate no power interruption at the power supply component, and
output a second output voltage in response to the input voltage being less than or equal to the reference voltage to the processor to indicate a power interruption at the power supply component; and
wherein the reference component is configured to:
generate the reference voltage based on the supply voltage when the DC voltage provided by the power supply component is at or above a threshold level, and
provide the reference voltage to the comparison component,
wherein, when the DC voltage drops below the threshold level to cause the supply voltage to drop during the power interruption, the reference component is configured to maintain the reference voltage at a same level as the reference voltage prior the power interruption to prevent a premature reboot or reinitialization of the seat peripheral device.

2. The seat peripheral device of claim 1, wherein the processor is configured to:
perform an operation of the seat peripheral device in response to the first output voltage from the comparison component, and
prepare the seat peripheral device for a shutdown or a reinitialization in response to the second output voltage from the comparison component.

3. The seat peripheral device of claim 1, wherein the cable includes a first end connected to the power supply component providing the DC voltage to the cable and a second end connected to the seat peripheral device to supply the supply voltage, and
wherein the supply voltage is a function of the DC voltage and a length of the cable between the power supply component and the seat peripheral device.

4. The seat peripheral device of claim 3, wherein the supply voltage is a function of the DC voltage, the length of the cable, and a power dissipation requirement of the seat peripheral device.

5. The seat peripheral device of claim 1, wherein the input voltage based on the supply voltage exceeds the reference voltage when the DC voltage is at or above the threshold level, and
wherein the input voltage based on the supply voltage is less than or equal to the reference voltage when the DC voltage drops below the threshold level during the power interruption.

6. The seat peripheral device of claim 1, wherein the reference component comprises:
a first transistor component including a first transistor that is deactivated when the DC voltage drops below the threshold level which causes the supply voltage to drop; and
a second transistor component including a second transistor that is deactivated, to maintain the reference voltage, by the second output voltage from the comparison component in response to the input voltage being less than or equal to the reference voltage when the DC voltage drops below the threshold level which causes the supply voltage to drop to reduce the input voltage.

7. The seat peripheral device of claim 6, wherein the second transistor component further includes a maintenance capacitor positioned parallel to the second transistor, and
wherein the second transistor component is configured to maintain the reference voltage at the same level as the reference voltage prior the power interruption using the maintenance capacitor while the second transistor is deactivated when the DC voltage dropping below the threshold level causes the supply voltage to drop.

8. The seat peripheral device of claim 6, wherein the first transistor includes a first collector directly connected to a node receiving the supply voltage, a first base connected to the node receiving the supply voltage via at least one resistor that causes a base voltage at the first base to be lower than the supply voltage, and a first emitter connected to a reference terminal of the comparison component that receives the reference voltage, and
wherein the second transistor includes a second collector connected to the reference terminal, a second base directly connected to an output of the comparison component, and a second emitter connected to a ground.

9. The seat peripheral device of claim 6, wherein the first transistor is a first Negative-Positive-Negative (NPN) transistor, and the second transistor is a second NPN transistor.

10. The seat peripheral device of claim 1, wherein the seat peripheral component further comprises:
an initialization component configured to maintain an output voltage of the comparison component as the second output voltage during initialization of the seat peripheral device.

11. A method of detecting a low voltage condition at a seat peripheral device for a transportation vehicle using a seat peripheral component coupled to a passenger seat, the seat peripheral component comprising a comparison component, a reference component, a processor electrically coupled to the comparison component, the method comprising:
generating, by the reference component, a reference voltage associated with a power supply component of the transportation vehicle based on a supply voltage supplied to the seat peripheral device when a direct current (DC) voltage provided by the power supply component is at or above a threshold level, wherein the supply voltage is supplied to the seat peripheral device via a cable connected to the power supply component configured to provide the DC voltage to the cable;
maintaining, by the reference component, the reference voltage at a same level as the reference voltage prior to a power interruption to prevent a premature reboot or a premature reinitialization of the seat peripheral device when the DC voltage drops below the threshold level to cause the supply voltage to drop during the power interruption;
providing, by the reference component, the reference voltage to the comparison component;
comparing, by the comparison component, an input voltage and the reference voltage, wherein the input voltage is based on the supply voltage;
outputting, by the comparison component, a first output voltage in response to the input voltage exceeding the reference voltage, to the processor to indicate no power interruption at the power supply component; and
outputting, by the comparison component, a second output voltage in response to the input voltage being less than or equal to the reference voltage, to the processor to indicate the power interruption at the power supply component.

12. The method of claim 11, further comprising
performing, by the processor, an operation of the seat peripheral device in response to the first output voltage from the comparison component, and
preparing, by the processor, the seat peripheral device for a shutdown or reinitialization in response to the second output voltage from the comparison component.

13. The method of claim 11, wherein the cable includes a first end connected to the power supply component providing the DC voltage to the cable and a second end connected to the seat peripheral device to supply the supply voltage, and
wherein the supply voltage is a function of the DC voltage and a length of the cable between the power supply component and the seat peripheral device.

14. The method of claim 13, wherein the supply voltage is a function of the DC voltage, the length of the cable, and a power dissipation requirement of the seat peripheral device.

15. The method of claim 11, wherein the input voltage based on the supply voltage exceeds the reference voltage when the DC voltage is at or above the threshold level, and
wherein the input voltage based on the supply voltage is less than or equal to the reference voltage when the DC voltage drops below the threshold level during the power interruption.

16. The method of claim 11, wherein the reference component comprises:
a first transistor component including a first transistor that is deactivated when the DC voltage drops below the threshold level which causes the supply voltage to drop; and
a second transistor component including a second transistor that is deactivated, to maintain the reference voltage, by the second output voltage from the comparison component in response to the input voltage being less than or equal to the reference voltage when the DC voltage drops below the threshold level which causes the supply voltage to drop to reduce the input voltage.

17. The method of claim 16, wherein the second transistor component further includes a maintenance capacitor positioned parallel to the second transistor, and
wherein second transistor component is configured to maintain the reference voltage at the same level as the reference voltage prior the power interruption using the maintenance capacitor while the second transistor is deactivated when the DC voltage dropping below the threshold level causes the supply voltage to drop.

18. The method of claim 16, wherein the first transistor includes a first collector directly connected to a node receiving the supply voltage, a first base connected to the node receiving the supply voltage via at least one resistor that causes a base voltage at the first base to be lower than the supply voltage, and a first emitter connected to a reference terminal of the comparison component that receives the reference voltage, and
wherein the second transistor includes a second collector connected to the reference terminal, a second base directly connected to an output of the comparison component, and a second emitter connected to a ground.

19. The method of claim 16, wherein the first transistor is a first Negative-Positive-Negative (NPN) transistor, and the second transistor is a second NPN transistor.

20. The method of claim 11, further comprising:
maintaining, by an initialization component, an output voltage of the comparison component as the second output voltage during initialization of the seat peripheral device.
